(19) United States
(12) Patent Application Publication
(10) Pub. No.: US 2026/0245597 A1
(43) Pub. Date: Aug. 20, 2026

(54) MEMORY DEVICE AND METHOD

(71) Applicant: TAIWAN SEMICONDUCTOR MANUFACTURING COMPANY, LTD., Hsinchu (TW)

(72) Inventors: Chun-Ying LEE, Hsinchu (TW); Yen-Hsiang HUANG, Hsinchu (TW); Chia-En HUANG, Hsinchu (TW)

(21) Appl. No.: 19/058,529

(22) Filed: Feb. 20, 2025

(51) Int. Cl. G11C 5/06; G11C 11/419; H10B 10/00

(52) U.S. Cl. CPC G11C 5/063; G11C 11/419; H10B 10/12

(57) ABSTRACT

A memory device includes first and second word lines, a bit line, and a memory cell. The memory cell includes first and second semiconductor devices correspondingly of different first and second types. The first semiconductor device includes a gate electrically coupled to the first word line, a first source/drain electrically coupled to the bit line, and a second source/drain electrically coupled to receive a first power supply voltage. The second semiconductor device includes a gate, a first source/drain electrically coupled to the bit line, and a second source/drain. The second word line is electrically coupled to the gate of the second semiconductor device, and the second source/drain of the second semiconductor device is floating. Alternatively, the gate of the second semiconductor device and the second source/drain of the second semiconductor device are electrically coupled to receive a second power supply voltage different from the first power supply voltage.

### BACKGROUND

An integrated circuit (“IC”) device includes one or more semiconductor devices represented in an IC layout diagram (also referred to as “layout diagram”, “IC layout”, or “layout”). A layout diagram is hierarchical and includes modules which carry out higher-level functions in accordance with the IC device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs. Examples of IC devices and cells correspondingly include memory devices and memory cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic block diagram of a memory device, in accordance with some embodiments.

FIGS. 2A, 2B, 2C are schematic circuit diagrams of a memory device, in accordance with some embodiments.

FIGS. 3A, 3B, 3C are schematic circuit diagrams of a memory device, in accordance with some embodiments.

FIG. 4A is a schematic perspective view of a stacked configuration of semiconductor devices configurable as a memory cell, in accordance with some embodiments.

FIGS. 4B, 4C are schematic cross-sectional views of a portion of a memory device, in accordance with some embodiments.

FIG. 4D is a schematic perspective view of a planar configuration of semiconductor devices configurable as a memory cell, in accordance with some embodiments.

FIG. 4E includes schematic layout views of various memory cells configured by semiconductor devices in a planar configuration, in accordance with some embodiments.

FIGS. 5A, 5B, 5C are schematic views of layouts of semiconductor devices of a first type in various memory devices, in accordance with some embodiments.

FIGS. 6A, 6B, 6C are schematic views of layouts of semiconductor devices of a second type in various memory devices, in accordance with some embodiments.

FIGS. 7A, 7B, 7C each include a schematic circuit diagram and a schematic view of a layout of a portion of a memory device, in accordance with some embodiments.

FIG. 8A includes schematic perspective views of various memory cells configured by semiconductor devices in a stacked configuration, in accordance with some embodiments.

FIG. 8B includes schematic perspective views of various memory cells configured by semiconductor devices in a planar configuration, in accordance with some embodiments.

FIG. 8C is a table summarizing various memory cell configurations, in accordance with some embodiments.

FIGS. 9A, 9B, 9C are flow charts of various methods, in accordance with some embodiments.

FIG. 10 is a block diagram of an electronic design automation (EDA) system in accordance with some embodiments.

FIG. 11 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a memory device comprises at least one memory cell each comprising first and second semiconductor devices of different first and second types. The first and second semiconductor devices are electrically coupled to a bit line, corresponding first and second power rails of different first and second power supply voltages, and one or more corresponding word lines, to be configured to store a datum being a first logic value or a different, second logic value. As a result, it is possible in one or more embodiments to perform a read operation of any of the first logic value and the second logic value from a memory cell of the memory device, without requiring a further circuit (sometimes referred to as “keeper” or “keeper circuit” or the like) to clamp a voltage on the bit line during the read operation. Such a keeper circuit is required in other approaches where each memory cell has a single transistor. Because keeper circuits are not required in a memory device in accordance with some embodiments, it is possible to achieve one or more improvements over the other approaches which require keeper circuits. Such improvements include, but are not limited to, reduced power consumption, reduced chip area, increased read margins for sensing by sense amplifiers, simplified control, or the like.

In at least one embodiment, the first and second semiconductor devices of each memory cell are arranged in different layers stacked one over another, e.g., in a stacked configuration sometimes referred to as a complementary field effect transistor (CFET) device. As a result, a memory array comprising multiple memory cells in stacked semiconductor devices in accordance with some embodiments causes no area impact (or no area increase) compared to memory arrays of the other approaches where each memory cell in has a single transistor.

In some embodiments, the first and second semiconductor devices of each memory cell are arranged in the same layer in a planar configuration. Although this planar configuration increases an area of a memory array in accordance with some embodiments compared to memory arrays of the other approaches, it is still possible to achieve one or more other advantages described herein due to the omission of keeper circuits. Memory cells and/or memory devices in accordance with some embodiments are applicable to various processes and/or semiconductor device types, including, but not limited to, CFET, Fin Field-Effect Transistor (FinFET), planar semiconductor device, or the like. Further advantages and/or effects are achievable in one or more embodiments as described herein.

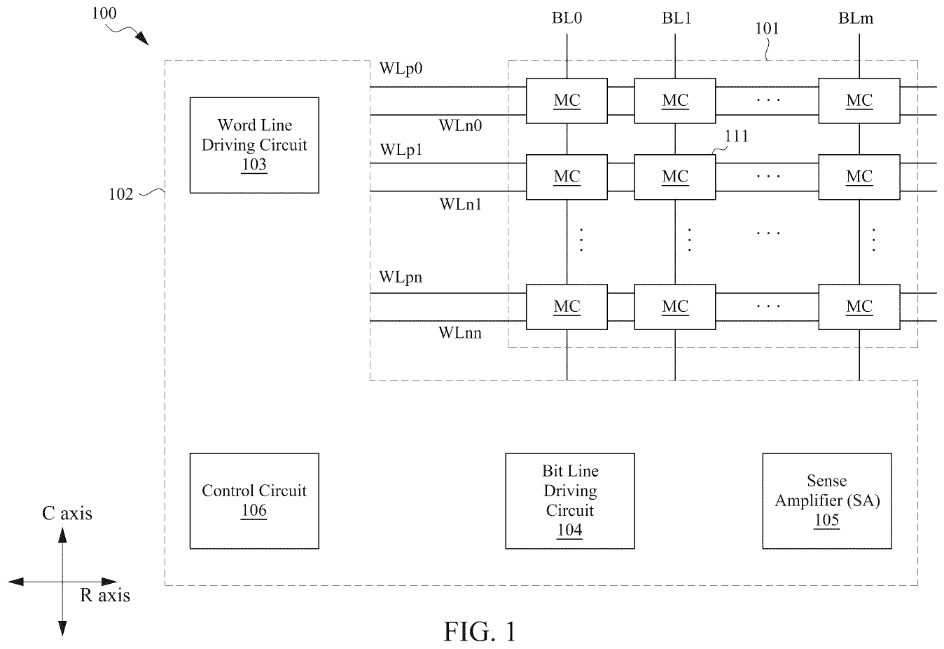

FIG. 1 is a schematic block diagram of a memory device 100, in accordance with some embodiments. A memory device is a type of an IC device. In at least one embodiment, a memory device is an individual IC device. In some embodiments, a memory device is included as a part of a larger IC device which comprises circuitry other than the memory device for other functionalities. The memory device 100 is a read-only memory (ROM) device, in one or more embodiments.

The memory device 100 comprises a memory array 101 of a plurality of memory cells MC, and a memory controller 102 (sometimes referred to as “memory control circuitry”) coupled to control an operation of the memory cells MC. In the memory array 101, the memory cells MC are arranged in a plurality of columns and a plurality of rows. The number of columns in the memory array 101 is the same as, or different from, the number of rows. Columns and rows in a memory array are sometimes referred to as memory columns and memory rows. The memory columns extend in a column direction, designated as C axis in the drawings. The memory rows extend in a row direction transverse to the column direction, and designated as R axis in the drawings. Each memory cell MC comprises a first semiconductor device of a first type, and a second semiconductor device of a second type different from the first type. In at least one embodiment, the first type is a P-type and the second type is an N-type. In one or more embodiments, the first type is the N-type and the second type is the P-type.

The memory device 100 further comprises a plurality of word lines extending along the rows of the memory array 101, and a plurality of bit lines extending along the columns of the memory array 101. The word lines are commonly referred to herein with a label WL, and the bit lines are commonly referred to herein with a label BL. The word lines are configured for transmitting addresses of memory cells MC to be read from. The word lines are sometimes referred to as “address lines.” The bit lines are configured for transmitting data read from the memory cells MC indicated by the addresses on the corresponding word lines. The bit lines are sometimes referred to as “data lines.” Various numbers of word lines and/or bit lines in the memory device 100 are within the scope of various embodiments.

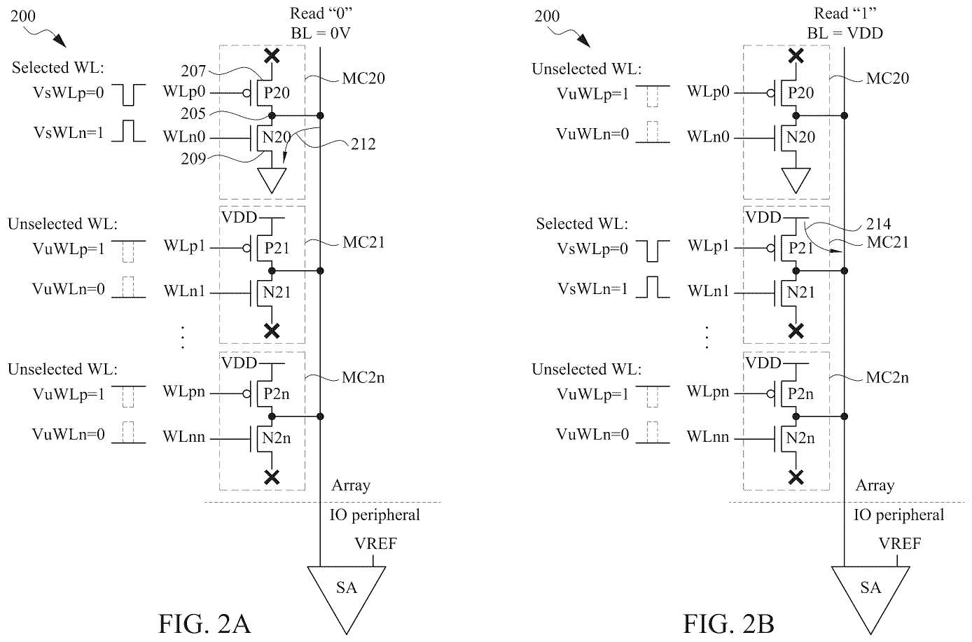

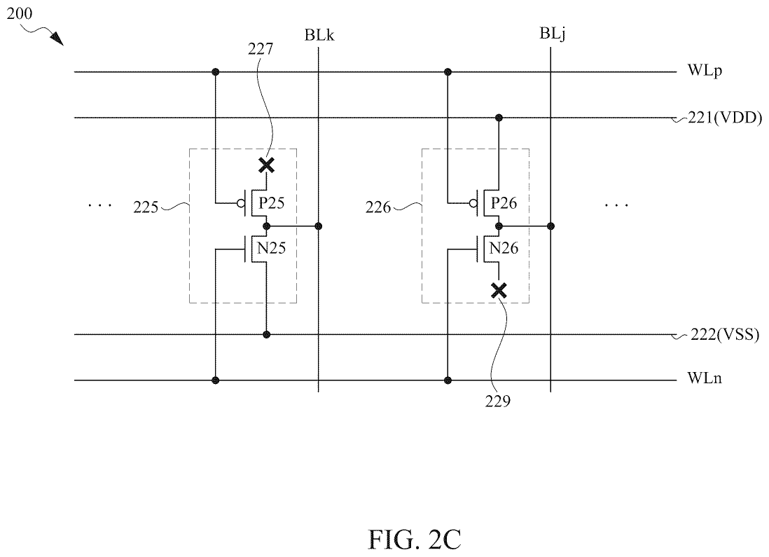

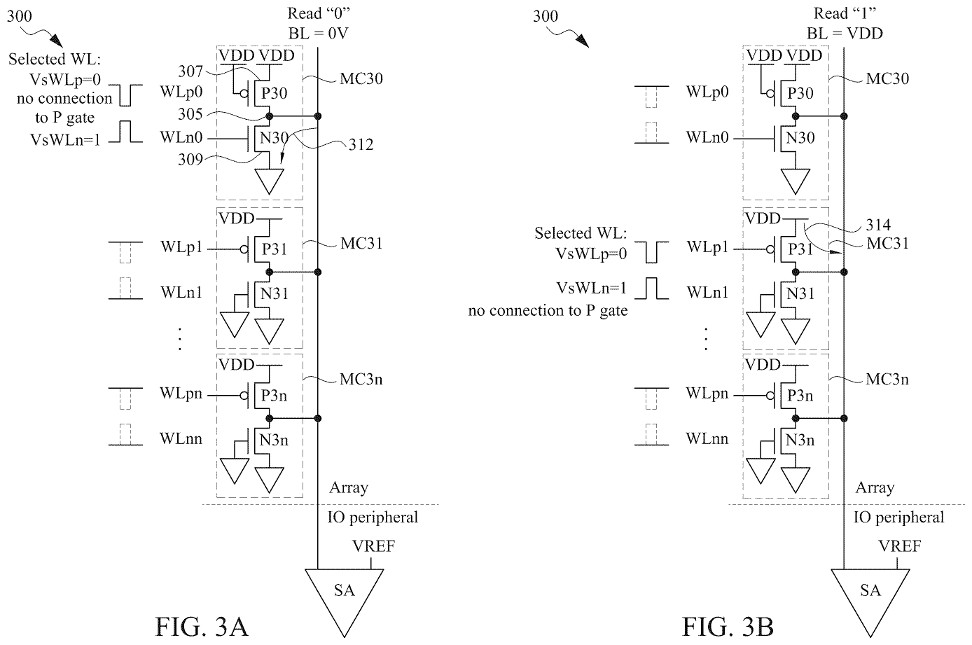

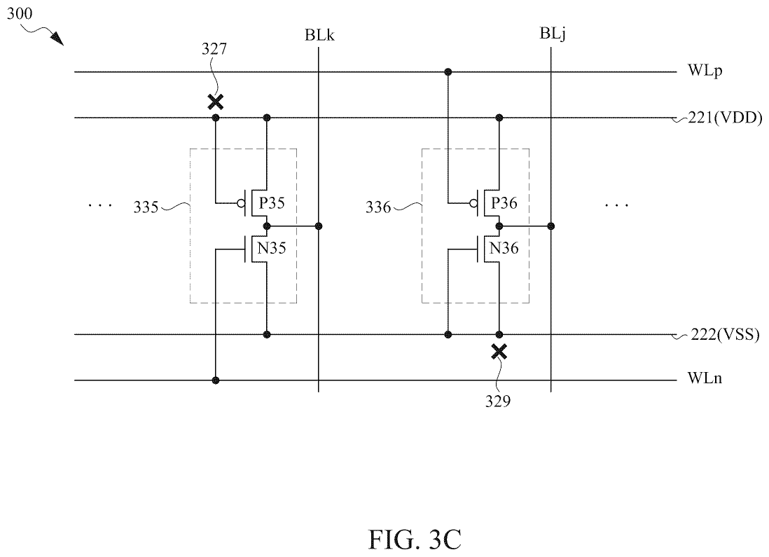

Memory cells MC in each memory row are electrically coupled to the memory controller 102 by a pair of word lines correspondingly labelled as WLp (e.g., WLp0, WLp1 to WLpn) and WLn (e.g., WLn0, WLn1 to WLnn). The word line WLp is configured to be electrically coupled to a P-type semiconductor device in a corresponding memory cell MC. The word line WLn is configured to be electrically coupled to an N-type semiconductor device in the corresponding memory cell MC. For example, a memory cell 111 in the memory array 101 comprises a P-type semiconductor device corresponding to the word line WLp1, and an N-type semiconductor device corresponding to the word line WLn1. In some embodiments, as described with respect to FIGS. 2A-2C, in the memory cell 111, the P-type semiconductor device is electrically coupled to the word line WLp1, and the N-type semiconductor device is electrically coupled to the word line WLn1. In at least one embodiment, as described with respect to FIGS. 3A-3C, in the memory cell 111, one of the P-type semiconductor device and the N-type semiconductor device is electrically coupled to the corresponding word line WLp1 or word line WLn1, whereas the other of the P-type semiconductor device and the N-type semiconductor device is not electrically coupled to the other corresponding word line WLp1 or word line WLn1, depending on a logic value, i.e., logic “0” or logic “1”, stored in the memory cell 111. A pair of word lines WLp, WLn is configured to correspondingly carry a pair of address signals, or access voltage, which are related, or correspond, to each other. For example, one address signal in the pair of address signals is an inverted signal of the other address signal. The pair of address signals is generated by and/or supplied from the memory controller 102.

Memory cells MC in each memory column are electrically coupled to the memory controller 102 by a corresponding bit line (e.g., BL0, BL1 to BLm). For example, in the memory cell 111, both the P-type semiconductor device and the N-type semiconductor device are electrically coupled to the corresponding bit line BL1.

In the example configuration in FIG. 1, the memory controller 102 comprises a word line driving circuit 103, a bit line driving circuit 104, a sense amplifier 105, and a control circuit 106. Various quantities of word line driving circuits, and/or bit line driving circuits, and/or sense amplifiers are within the scopes of various embodiments.

The word line driving circuit 103 is configured to decode a row address of one or more memory cells MC selected to be accessed in a read operation. For example, the word line driving circuit 103 comprises a plurality of word line drivers, or the like, each coupled to one or more word lines of the memory array 101. The word line driving circuit 103 is configured to supply, through the corresponding word line drivers, or the like, a set of access voltages to the selected word line(s) corresponding to the decoded row address, and a different set of voltages (e.g., zero) to the other, unselected word lines.

The bit line driving circuit 104 is configured to decode a column address of one or more memory cells MC selected to be accessed in a read operation. In some embodiments, the bit line driving circuit 104 comprises one or more bit line multiplexers each coupled to one or more bit lines of the memory array 101. The bit line driving circuit 104 is configured to supply, through the bit line multiplexers, a set of voltages to the selected bit line(s) corresponding to the selected memory cells MC to be accessed, and a different set of voltages to the other, unselected bit lines. In at least one embodiment, unselected bit lines are left floating. For example, the bit line driving circuit 104 comprises one or more pre-charging circuits configured to pre-charge the selected bit line(s) to a pre-charge voltage in a read operation. In some embodiments, the selected bit line(s) is/are not pre-charged.

The sense amplifier 105 is configured to sense, and output, data read from the accessed memory cells MC and retrieved through the corresponding bit line(s).

The control circuit 106 is configured to control operations of the word line driving circuit 103, bit line driving circuit 104, sense amplifier 105 and/or other components in the memory controller 102. In at least one embodiment, the memory controller 102 further includes one or more clock generators for providing clock signals for various components of the memory device 100, one or more input/output (I/O) circuits for data exchange with external devices, and/or one or more sub-controllers for controlling various operations in the memory device 100. The described memory device configuration is an example, and other memory device configurations are within the scopes of various embodiments.

FIGS. 2A, 2B, 2C are schematic circuit diagrams of a memory device 200, in accordance with some embodiments. In some embodiments, the memory device 200 corresponds to the memory device 100 and/or includes one or more memory cells corresponding to one or more memory cells MC in the memory device 100. For simplicity, corresponding components in FIGS. 2A-2C are designated by the same reference numerals.

In FIG. 2A, the memory device 200 comprises memory cells MC20, MC21 . . . MC2n arranged along a memory column and coupled through a bit line BL to a sense amplifier SA. The memory cells MC20, MC21 . . . MC2n are arranged in a memory array corresponding to the memory array 101. The bit line BL corresponds to one or more of the bit lines described with respect to FIG. 1. The sense amplifier SA is part of memory control circuitry sometimes referred to as input/output (IO) peripheral.

Each of memory cells MC20, MC21 . . . MC2n comprises a first semiconductor device of a first type, and a second semiconductor device of a second type different from the first type. For example, the first semiconductor device of the first type is a P-type semiconductor device, such as transistors P20, P21, . . . P2n, and the second semiconductor device of the second type is an N-type semiconductor device, such as transistors N20, N21, . . . N2n. The circuit arrangement of the P-type transistor and N-type transistor in each memory cell in FIG. 2A does not necessarily correspond to the physical arrangement of the transistors. In some embodiments, one of the P-type transistor and the N-type transistor in each memory cell is physically over the other in a stacked configuration, e.g., a CFET device. In some embodiments, the P-type transistor is physically over the N-type transistor. In some further embodiments, the N-type transistor is physically over the P-type transistor. In at least one embodiment, the P-type transistor and the N-type transistor in each memory cell are physically arranged at the same level or in the same layer, in a planar configuration.

Each of the memory cells MC20, MC21 . . . MC2n corresponds to a pair of word lines, such as word lines WLp0 and WLn0, WLp1 and WLn1, . . . WLpn and WLnn. The gates of the P-type and N-type transistors in each memory cell are electrically coupled to the corresponding word lines. For example, gates of the transistors P20, N20 are electrically coupled to the corresponding word lines WLp0 and WLn0. First source/drains of the P-type and N-type transistors in each memory cell are electrically coupled to the bit line BL. For example, the first source/drains (or a common source/drain) 205 of the transistors P20, N20 are electrically coupled to the bit line BL.

Depending on a datum (or a logic value) stored in a memory cell, a second source/drain of one of the P-type and N-type transistors in the memory cell is electrically coupled to a corresponding power supply voltage, whereas a second source/drain of the other of the P-type and N-type transistors in the memory cell is left electrically floating or is not electrically coupled to the corresponding power supply voltage. A power supply voltage VDD corresponds to P-type transistors, and a power supply voltage VSS corresponds to N-type transistors. VDD is an example of one of first and second power supply voltages, and VSS is an example of the other of the first and second power supply voltages. A datum stored in a memory cell is logic “1” or logic “0”. Logic “1” is an example of one of first and second logic values, and logic “0” is an example of the other of the first and second logic values.

In the example configuration in FIG. 2A, the memory cell MC20 is configured to store, e.g., logic “0”. Specifically, a second source/drain 207 of the transistor P20 is floating, whereas a second source/drain 209 of the transistor N20 is electrically coupled to the corresponding power supply voltage, i.e., VSS. The memory cell MC21 is configured to store a different logic value from the memory cell MC20, e.g., logic “1”. Specifically, a second source/drain (not numbered) of the transistor P21 is electrically coupled to the corresponding power supply voltage, i.e., VDD, whereas a second source/drain (not numbered) of the transistor N21 is floating. In at least one embodiment, the configuration of the memory cell MC20 corresponds to logic “1” and the configuration of memory cell MC21 corresponds to logic “0”.

In an example read operation, a memory controller (not shown) of the memory device 200 is configured to supply a first pair of inverted signals to a corresponding pair of word lines of each selected memory cell, and a different, second pair of inverted signals to a corresponding pair of word lines of each unselected memory cell. In the example configuration in FIG. 2A, the memory cell MC20 is selected, whereas other memory cells coupled to the bit line BL are unselected. The first pair of inverted signals supplied to the corresponding word lines WLp0, WLn0 of the selected memory cell MC20 includes VsWLp of a low level (e.g., VSS or logic “0”) and VsWLn of a high level (e.g., VDD or logic “1”). The second pair of inverted signals supplied to the corresponding word lines of the other, unselected memory cells includes VuWLp of a high level (e.g., VDD or logic “1”) and VuWLn of a low level (e.g., VSS or logic “0”). In some embodiments, each pair of inverted signals is generated by an inverter. For example, the memory controller supplies one of the pair of inverted signals to an input on the inverter and also to one of the word line in a pair of word lines, whereas the other word line in the pair of word lines is electrically coupled to the output of the inverter to receive the other of the pair of inverted signals.

The first pair of inverted signals supplied to a corresponding pair of word lines of each selected memory cell causes the corresponding transistors of each selected memory cell to turn ON, and is sometimes referred to as access voltages. For example, VsWLp of VSS supplied through the word line WLp0 to the gate of the transistor P20 and causing the transistor P20 to turn ON is an example of one of first and second access voltages, whereas VsWLn of VDD supplied through the word line WLn0 to the gate of the transistor N20 and causing the transistor N20 to turn ON is an example of the other of the first and second access voltages. The P-type and N-type transistors in each unselected memory cell are not turned ON, i.e., remain turned OFF, due to the corresponding pair of inverted signals VuWLp, VuWLn supplied to their gates.

Because the second source/drain 207 of the transistor P20 is floating, the transistor P20 turned ON by VsWLp does not affect a bit line voltage on the bit line BL. The second source/drain 209 of the transistor N20 is electrically coupled to VSS which is applied to the bit line BL through the transistor N20 turned ON by VsWLn. As a result, the bit line voltage on the bit line BL is pulled to VSS (BL=0V) or the ground, as schematically indicated by an arrow 212. The sense amplifier SA has a first input coupled to the bit line BL and a second input coupled to receive a reference voltage VREF. The sense amplifier SA is configured to compare VREF with the bit line voltage and, in response to the bit line voltage becoming lower than VREF, sense a logic “0” stored in the memory cell MC20. The described example read operation reads out logic “0” from a selected memory cell, and is sometimes referred to as a read “0” operation.

In the example read operation described with respect to FIG. 2A, there is no further circuit (e.g., a keeper circuit or the like) required to clamp the bit line voltage during the read operation. In some embodiments, this is an improvement over other approaches where each memory cell has a single transistor (e.g., an N-type transistor), and a keeper circuit is required. Such a keeper circuit is arranged in the IO peripheral and is configured to cause a current (e.g., a direct current or DC current) to flow from the IO peripheral, through a selected bit line BL and a turned ON transistor of a selected memory cell storing logic “0”, to the ground. In some situations, the keeper circuit causes the DC current, e.g., a constant DC current, to flow to the ground before a sense amplifier senses a datum stored in the selected memory cell. The presence of a keeper circuit increases the area of the IO peripheral, and further requires additional control for turning ON or OFF the keeper circuit depending on an operation of the memory device in the other approaches. Such additional area in the IO peripheral and/or additional control related to keeper circuits are avoided or omitted in memory devices in accordance with some embodiments which do not include keeper circuits and/or do not require any further circuit to cause a current to flow to the ground in a read operation. As a result, it is possible in one or more embodiments to achieve one or more improvements including, but not limited to, reduced power consumption, reduced chip area, simplified control, or the like.

In FIG. 2B, another example read operation, e.g., a read “1” operation which reads out logic “1” from a selected memory cell, is performed in the memory device 200.

In the example configuration in FIG. 2B, the memory cell MC21 storing logic “1” is selected, whereas other memory cells coupled to the bit line BL are unselected. The pair of access voltages VsWLp and VsWLn is supplied to the corresponding word lines WLp1, WLn1 and turns ON the corresponding transistors P21, N21, whereas the P-type and N-type transistors in each unselected memory cell are not turned ON, i.e., remain turned OFF, due to the corresponding pair of inverted signals VuWLp, VuWLn supplied to their gates. Because the second source/drain of the transistor N21 is floating, the transistor N21 turned ON by VsWLn does not affect the bit line voltage on the bit line BL. The second source/drain of the transistor P21 is electrically coupled to VDD which is applied to the bit line BL through the transistor P21 turned ON by VsWLp. As a result, the bit line voltage on the bit line BL is pulled to VDD (BL=VDD), as schematically indicated by an arrow 214. The sense amplifier SA is configured to compare VREF with the bit line voltage and, in response to the bit line voltage becoming higher than VREF, sense a logic “1” stored in the memory cell MC21. Again, no keeper circuit is required in a read “1” operation, in accordance with some embodiments.

Compared to the other approaches, a further improvement includes increased read margins for sense amplifiers, in accordance with some embodiments. As described herein, a voltage difference between the inputs of the sense amplifier SA is as large as VREF-OV in a read “0” operation, or VDD-VREF in a read “1” operation. In other approaches where each memory cell has a single transistor (e.g., an N-type transistor), a voltage difference between inputs of a sense amplifier is VREF-VRO (where VR0>0V) in a read “0” operation, or VR1-VREF (where VR1<VDD) in a read “1” operation. Because the voltage difference between the inputs of the sense amplifier SA in memory devices in accordance with some embodiments is larger than in the other approaches, increased read margins are achievable for sense amplifiers with further improvements in one or more of read reliability, accuracy, speed, or the like.

In FIG. 2C, a further portion of the memory device 200 is schematically illustrated. Compared to FIGS. 2A-2B, which schematically show memory cells of the memory device 200 along a memory column, FIG. 2C schematically show memory cells of the memory device 200 along a memory row.

Specifically, each of memory cells 225, 226 in the memory row illustrated in FIG. 2C is electrically coupled to a pair of word lines WLp, WLn which corresponds to one or more of the pairs of word lines described with respect to FIGS. 1, 2A. In at least one embodiment, the word lines WLp, WLn extend continuously along multiple memory cells in the memory row. The memory cells 225, 226 are electrically coupled correspondingly to different bit lines BLk, BLj each of which corresponds to one or more of the bit lines described with respect to FIG. 1, where 0≤k<j≤m.

A power rail 221 configured to carry a first power supply voltage (e.g., VDD), and a power rail 222 configured to carry a second power supply voltage (e.g., VSS) are also provided in the example configuration in FIG. 2C. The power rail 221 is referred to herein as a VDD power rail and is an example of one of first and second power rails, whereas the power rail 222 is referred to herein as a VSS power rail and is an example of the other of first and second power rails. In some embodiments, each of the VDD, VSS power rails extends continuously along a memory row or a memory column, and is selectively coupled to one or more of the memory cells in the memory row or the memory column, depending on the datum stored in each memory cell. For example, the memory cell 225 is configured to store logic “0” like the memory cell MC20, and has a second source/drain of a transistor N25 electrically coupled to the VSS power rail 222, and a second source/drain of a transistor P25 floating as schematically illustrated by an X mark 227. In another example, the memory cell 226 is configured to store logic “1” like the memory cell MC21, and has a second source/drain of a transistor P26 electrically coupled to the VDD power rail 221, and a second source/drain of a transistor N26 floating as schematically illustrated by an X mark 229.

In a read operation, the access voltages described with respect to FIGS. 2A-2B are supplied to the word lines WLp, WLn, and turn ON transistors P25, N25, P26, N26. The bit line BLk is pulled to VSS through the turned ON transistor N25 and the bit line BLj is pulled to VDD through the turned ON transistor P26, resulting in logic “0” being read out from the memory cell 225 through the bit line BLk, and logic “1” being read out from the memory cell 226 through the bit line BLj, as described with respect to FIGS. 2A-2B.

FIGS. 3A, 3B, 3C are schematic circuit diagrams of a memory device 300, in accordance with some embodiments. In some embodiments, the memory device 300 corresponds to the memory device 100 and/or includes one or more memory cells corresponding to one or more memory cells MC in the memory device 100. For simplicity, corresponding components in FIGS. 2A-2C, 3A-3C are designated by the same reference numerals.

In FIG. 3A, the memory device 300 comprises memory cells MC30, MC31 . . . MC3n arranged along a memory column and coupled through the bit line BL to the sense amplifier SA. Each of memory cells MC30, MC31 . . . MC3n comprises a P-type semiconductor device, such as transistors P30, P31, . . . P3n, and an N-type semiconductor device, such as transistors N30, N31, . . . N3n. The circuit arrangement of the P-type transistor and N-type transistor in each memory cell in FIG. 3A does not necessarily correspond to the physical arrangement of the transistors. In some embodiments, one of the P-type transistor and the N-type transistor in each memory cell is physically over the other in a stacked configuration, e.g., a CFET device. In some embodiments, the P-type transistor is physically over the N-type transistor. In some further embodiments, the N-type transistor is physically over the P-type transistor. In at least one embodiment, the P-type transistor and the N-type transistor in each memory cell are physically arranged at the same level or in the same layer, in a planar configuration.

Each of the memory cells MC30, MC31 . . . MC3n corresponds to a pair of word lines, such as word lines WLp0 and WLn0, WLp1 and WLn1, . . . WLpn and WLnn. First source/drains of the P-type and N-type transistors in each memory cell are electrically coupled to the bit line BL. For example, the first source/drains (or a common source/drain) 305 of the transistors P30, N30 are electrically coupled to the bit line BL. Second source/drains of the P-type and N-type transistors in each memory cell are electrically coupled to the corresponding power supply voltages. For example, in the memory cell MC30, the second source/drain 307 of the transistor P30 is electrically coupled to the corresponding power supply voltage VDD, and the second source/drain 309 of the transistor N30 is electrically coupled to the corresponding power supply voltage VSS.

Depending on a datum (or a logic value) stored in a memory cell, a gate of one of the P-type and N-type transistors in the memory cell is electrically coupled to the corresponding word line, whereas a gate of the other of the P-type and N-type transistors in the memory cell is electrically coupled to the corresponding power supply voltage (or to the second source/drain) instead of the corresponding word line. In the example configuration in FIG. 3A, the memory cell MC30 is configured to store, e.g., logic “0”. Specifically, the gate of the transistor N30 is electrically coupled to the corresponding word line WLn0, whereas the gate of the transistor P30 is electrically coupled to the corresponding power supply voltage VDD (or to the second source/drain 307) instead of the corresponding word line WLp0. In other words, the transistor P30 is always (or hardwired) in the turned OFF state. The memory cell MC31 is configured to store a different logic value from the memory cell MC30, e.g., logic “1”. Specifically, the gate of the transistor P31 is electrically coupled to the corresponding word line WLp1, whereas the gate of the transistor N31 is electrically coupled to the corresponding power supply voltage VSS (or to the second source/drain of the transistor N31) instead of the corresponding word line WLn1. In other words, the transistor N31 is always (or hardwired) in the turned OFF state. In at least one embodiment, the configuration of the memory cell MC30 corresponds to logic “1” and the configuration of memory cell MC31 corresponds to logic “0”.

In an example read operation, a memory controller (not shown) of the memory device 300 is configured to supply a first pair of inverted signals to a corresponding pair of word lines of each selected memory cell, and a different, second pair of inverted signals to a corresponding pair of word lines of each unselected memory cell, in a manner similar to that described with respect to FIG. 2A. In the example configuration in FIG. 3A, the memory cell MC30 is selected, whereas other memory cells coupled to the bit line BL are unselected. The first pair of inverted signals supplied to the corresponding word lines WLp0, WLn0 of the selected memory cell MC30 includes access voltages VsWLp, VsWLn. The second pair of inverted signals supplied to the corresponding word lines of the other, unselected memory cells includes VuWLp, VuWLn.

The access voltages VsWLp, VsWLn supplied to the corresponding pair of word lines of the selected memory cell turn ON one of the P-type and N-type transistors in the selected memory cell memory cell, because the gate of the other transistor is not electrically coupled to the corresponding word line (or the other transistor is always turned OFF) as described herein. The P-type and N-type transistors in each unselected memory cell are not turned ON, i.e., remain turned OFF. For example, the access voltage VsWLp of VSS is supplied to the word line WLp0 which is, however, not electrically coupled to the gate of the transistor P30 of the selected memory cell MC30. Thus, the transistor P30 remains turned OFF and does not affect a bit line voltage on the bit line BL. The access voltage VsWLn of VDD is supplied to the word line WLn0 electrically coupled to the gate of the transistor N30 and turns ON the transistor N30. The second source/drain 309 of the transistor N30 is electrically coupled to VSS which is applied to the bit line BL through the transistor N30 turned ON by VsWLn. As a result, the bit line voltage on the bit line BL is pulled to VSS (BL=0V) or the ground, as schematically indicated by an arrow 312. The sense amplifier SA is configured to compare VREF with the bit line voltage and, in response to the bit line voltage becoming lower than VREF, sense a logic “0” stored in the memory cell MC30. The described example read operation reads out logic “0” from a selected memory cell, and is sometimes referred to as a read “0” operation. In the example read operation described with respect to FIG. 3A, there is no further circuit (e.g., a keeper circuit or the like) required to clamp the bit line voltage during the read operation.

In FIG. 3B, another example read operation, e.g., a read “1” operation which reads out logic “1” from a selected memory cell, is performed in the memory device 300.

In the example configuration in FIG. 3B, the memory cell MC31 storing logic “1” is selected, whereas other memory cells coupled to the bit line BL are unselected. The pair of access voltages VsWLp and VsWLn is supplied to the corresponding word lines WLp1, WLn1, and turns ON the transistor P31 but not the transistor N31 which is always turned OFF, whereas the P-type and N-type transistors in each unselected memory cell are not turned ON, i.e., remain turned OFF.

The transistor N31 remains turned OFF and does not affect a bit line voltage on the bit line BL. The second source/drain of the transistor P31 is electrically coupled to VDD which is applied to the bit line BL through the transistor P31 turned ON by VsWLp. As a result, the bit line voltage on the bit line BL is pulled to VDD (BL=VDD), as schematically indicated by an arrow 314. The sense amplifier SA is configured to compare VREF with the bit line voltage and, in response to the bit line voltage becoming higher than VREF, sense a logic “1” stored in the memory cell MC31. Again, no keeper circuit is required in a read “1” operation, in accordance with some embodiments.

In FIG. 3C, a further portion of the memory device 300 is schematically illustrated. Compared to FIGS. 3A-3B, which schematically show memory cells of the memory device 300 along a memory column, FIG. 3C schematically show memory cells of the memory device 300 along a memory row, in a manner similar to FIG. 2C.

In FIG. 3C, each of the word lines WLp, WLn is selectively connected to, or disconnected from, the gate of a corresponding P-type or N-type transistor in a memory cell in the memory row, depending on the datum stored in the memory cell. For example, the memory cell 335 is configured to store logic “0” like the memory cell MC30, and has a gate of a transistor N35 electrically coupled to the corresponding word line WLn. However, a gate of a transistor P35 is electrically disconnected from the corresponding word line WLp, as schematically illustrated by an X mark 327. Instead, the gate of the transistor P35 is electrically coupled to the VDD power rail 221. In another example, the memory cell 336 is configured to store logic “1” like the memory cell MC31, and has a gate of a transistor P36 electrically coupled to the corresponding word line WLp. However, a gate of a transistor N36 is electrically disconnected from the corresponding word line WLn, as schematically illustrated by an X mark 329. Instead, the gate of the transistor N36 is electrically coupled to the VSS power rail 222.

In a read operation, the access voltages described with respect to FIGS. 3A-3B are supplied to the word lines WLp, WLn, and turn ON transistors N35, P36. However, the transistors P35, N36 remain turned OFF. The bit line BLk is pulled to VSS through the turned ON transistor N35 and the bit line BLj is pulled to VDD through the turned ON transistor P36, resulting in logic “0” being read out from the memory cell 335 through the bit line BLk, and logic “1” being read out from the memory cell 336 through the bit line BLj, as described with respect to FIGS. 3A-3B. One or more advantages described herein with respect to the memory device 200 are achievable by the memory device 300, in accordance with some embodiments.

Compared to the memory device 200, the memory device 300 in one or more embodiments provide reduced word line front end capacitance loading. Generally, capacitance loading related to a transistor comprises parasitic capacitance between a gate of the transistor and one or more of a source, a drain, a body of the transistor. In each memory cell in the memory device 300, one of the transistor PM and transistor NM is electrically coupled to be in the always-OFF state where the gate of the transistor is electrically coupled to the corresponding power supply voltage VDD or VSS. As a result, capacitance loading of the memory cell is reduced in one or more embodiments.

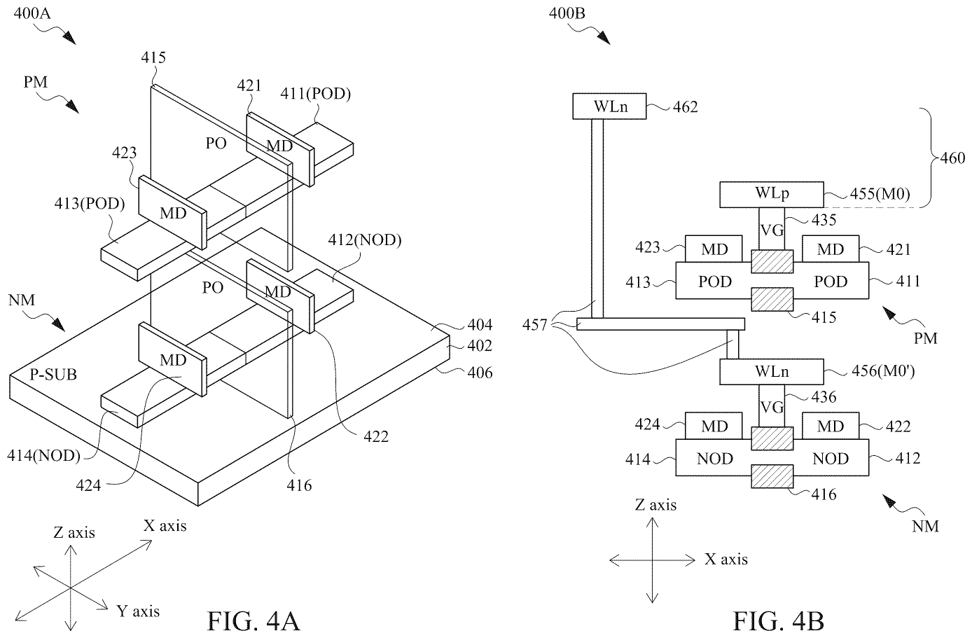

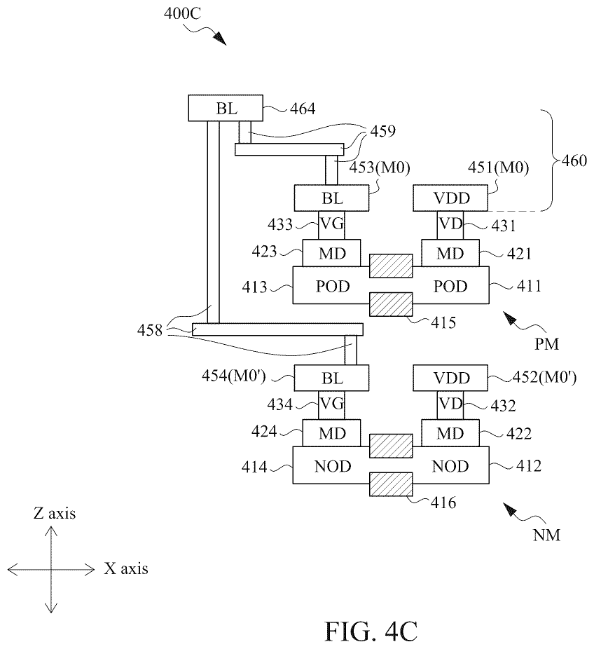

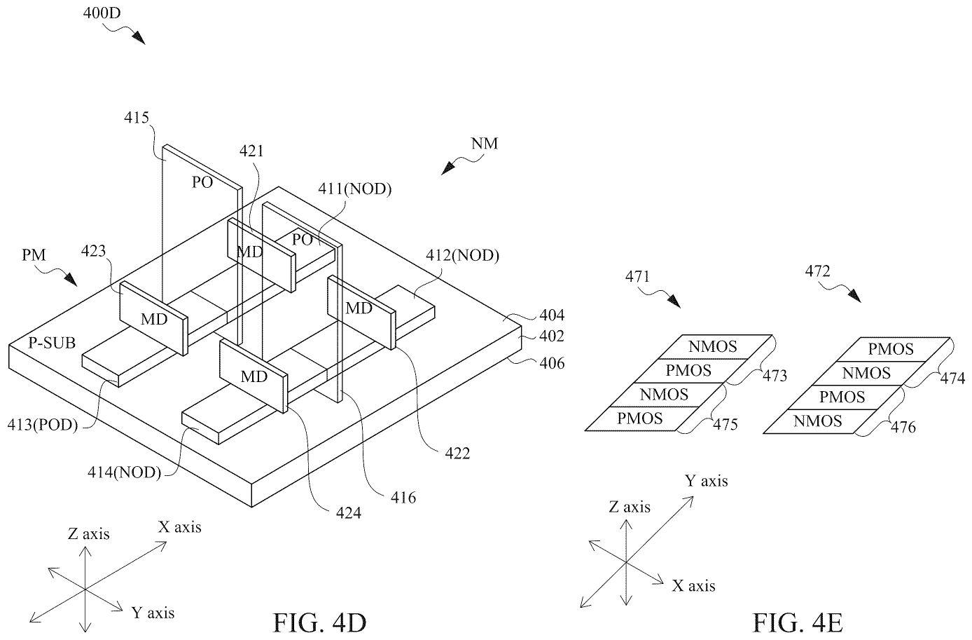

FIG. 4A is a schematic perspective view of a stacked configuration of semiconductor devices configurable as a memory cell, in accordance with some embodiments. The stacked configuration in FIG. 4A corresponds to a CFET device 400A which is, in one or more embodiments, configurable as a memory cell corresponding to one or more memory cells described with respect to FIGS. 1, 2A-2C, 3A-3C.

A CFET device comprises a top semiconductor device over a bottom semiconductor device of a different semiconductor type from that of the top semiconductor device. In the CFET device 400A, the top semiconductor device is a P-type semiconductor device, i.e., P-type transistor PM, and the bottom semiconductor device is an N-type semiconductor device, i.e., N-type transistor NM. The top semiconductor device belongs to an upper layer or top layer (sometimes referred to herein as Layer A), and the bottom semiconductor device belongs to a lower layer or bottom layer (sometimes referred to herein as Layer B). The CFET device 400A is an example of a P-type semiconductor device stacked on an N-type semiconductor device. This stacked configuration, or stacked structure, is sometimes referred to as a P-on-N configuration (or P-on-N structure). An example of a reversed, N-on-P configuration (or N-on-P structure) in which an N-type semiconductor device is stacked on a P-type semiconductor device is within the scopes of various embodiments.

The stacked structure comprising the transistors PM, NM is formed over a front side 404 of a substrate 402 which also has a back side 406. A thickness direction of the substrate 402 is also a thickness direction of the CFET device 400A, and is designated as the Z axis in the drawings. In some embodiments, the substrate 402 comprises a semiconductor material, such as silicon, silicon germanium (SiGe), gallium arsenic, or other suitable semiconductor materials. In some embodiments, the substrate 402 comprises a dielectric material, such as silicon nitride, silicon oxide, ceramic, glass, or other suitable materials. In some embodiments, the substrate 402 comprises a multi-layer structure. In some embodiments, the substrate 402 is omitted, or comprises an insulation layer that replaces an initial semiconductor bulk used during manufacture.

Each of the transistor PM and transistor NM comprises an active region. Active regions are sometimes referred to as oxide-definition (OD) regions or source/drain regions, and are schematically illustrated in the drawings with labels including “OD.” For example, the transistor PM comprises an active region POD, and the transistor NM comprises an active region NOD. The active region POD is stacked on the active region NOD along the thickness direction (or Z axis) of the substrate 402. The active regions POD, NOD are elongated along an X axis which is an example of a first direction or a second direction. The active regions POD, NOD include P-type dopants or N-type dopants to form one or more circuit elements or semiconductor devices. An active region configured to form one or more P-type semiconductor devices, e.g., P-channel metal-oxide semiconductor (PMOS) devices, is sometimes referred to as “PMOS active region,” and an active region configured to form one or more N-type semiconductor devices, e.g., N-channel metal-oxide semiconductor (NMOS) devices, is sometimes referred to as “NMOS active region.” In the example configuration described with respect to FIG. 3A, the active region POD comprises a PMOS active region, and the active region NOD comprises an NMOS active region. In some embodiments, the active regions POD, NOD are electrically isolated, and physically spaced along the Z axis, from each other by a dielectric layer (not shown).

The transistor PM further comprises a gate 415 which overlaps, or is stacked along the thickness direction of the substrate 402 over, a corresponding gate 416 of the transistor NM. The gate 415 is electrically isolated from the gate 416. The gates 415, 416 are elongated along a Y axis which is an example of the second direction or the first direction. The gates 415, 416 comprise a conductive material, such as, polysilicon, metals, or the like. Gates are sometimes schematically illustrated in the drawings with labels including “PO” (polysilicon) or “MG” (metal gate). In the example configuration in FIG. 4A, the gates 415, 416 are all-around gates which extend around corresponding channels (not numbered) configured by the corresponding active regions POD, NOD. The transistors with all-around gates are sometimes referred to as Gate-All-Around (GAA) transistors. A gate dielectric (not shown) is between each of the gates 415, 416 and the corresponding channel, and extends around the channel. Example materials of the gate dielectric include high-k dielectric materials, or the like.

Each of the active regions POD, NOD comprises a pair of source/drains on opposite sides of the corresponding gate 415, 416, and are connected by the corresponding channel. For example, the active region POD comprises source/drains 411, 413 of the transistor PM which are connected by the corresponding channel surround by the gate 415. For a further example, the active region NOD comprises source/drains 412, 414 of the transistor NM which are connected by the corresponding channel surround by the gate 416.

The CFET device 400A further comprises source/drain contacts in electrical contact with corresponding source/drains in the active regions POD, NOD. Source/drain contacts are sometimes referred to as metal-to-device (MD) contacts, and are schematically designated in the drawings with labels including “MD.” Source/drain contacts of a top semiconductor device are sometimes referred to as MD contacts. Source/drain contacts of a bottom semiconductor device are sometimes referred to as BMD contacts. For simplicity, an MD contact herein refers to either an MD contact for the top semiconductor device or a BMD contact for the bottom semiconductor device, unless specified otherwise. An MD contact includes a conductive material in electrical contact with a corresponding source/drain in the corresponding active region to define an electrical connection from the source/drain to a further conductive structure or circuitry of a memory device, an IC device including the memory device, or to outside circuitry. MD contacts are arranged alternatingly with gates along the X axis. In the example configuration in FIG. 4A, MD contacts 421, 423 are over and in electrical contact with the corresponding source/drains 411, 413 of the transistor PM, and a MD contacts 422, 424 are over and in electrical contact with the corresponding source/drains 412, 414 of the transistor NM.

FIG. 4B is a schematic cross-sectional view of a portion of a memory device 400B, in accordance with some embodiments. In some embodiments, the portion of the memory device 400B in FIG. 4B corresponds to the CFET device 400A. For simplicity, corresponding components in FIGS. 4A-4B are designated by the same reference numerals.

The memory device 400B comprises vias (or via structures) over and in electrical contact with the gates and MD contacts of the transistors PM, NM. A via over and in electrical contact with an MD contact is sometimes referred to as via-to-device (VD) via. A via over and in electrical contact with a gate is sometimes referred to as via-to-gate (VG) via. VD and VG vias are schematically illustrated in the drawings with the corresponding labels including “VD” and “VG.” In the example configuration in FIG. 4B, VG vias 435, 436 are correspondingly over and in electrical contact with the gates 415, 416. Examples of VD vias are described with respect to FIG. 4C. The VG via 436 and/or one or more VD vias for the transistor NM is/are physically arranged, along the Z axis, between the transistors PM, NM. Other configurations are within the scopes of various embodiments. For example, one or more VG vias and/or VD vias for bottom semiconductor devices such as the transistor NM are physically arranged below the transistor NM, in one or more embodiments. An example material of VD vias and/or VG vias includes metal.

A plurality of metal layers and via layers are sequentially and alternatingly arranged over the VD, VG vias of the transistor PM in a redistribution structure 460. The lowermost metal layer immediately over and in electrical contact with the VD, VG vias is an M0 (metal-zero) layer, a next metal layer immediately over the M0 layer is an M1 layer, a next metal layer immediately over the M1 layer is an M2 layer, or the like. Conductive patterns in the M0 layer are referred to as M0 conductive patterns, conductive patterns in the M1 layer are referred to as MI conductive patterns, or the like. A via layer Vn is arranged between and electrically couple the Mn layer and the Mn+1 layer, where n is an integer from zero and up. For example, a via-zero (V0) layer is the lowermost via layer which is arranged between and electrically couple the M0 layer and the M1 layer. Other via layers are V1, V2, or the like. Vias in the VO layer are referred to as V0 vias, vias in the V1 layer are referred to as V1 vias, or the like. In some embodiments, the memory device 400B further comprises a back side redistribution structure (not shown) with various back side metal layers and back side via layers under the transistor NM. In some embodiments, the back side redistribution structure comprises one or more VDD and/or VSS power rails.

In the example configuration in FIG. 4B, the M0 layer comprises a conductive pattern 455 over and in electrical contact with the VG via 435. The conductive pattern 455 is a word line pattern configured as, or electrically coupled to, a word line WLp which corresponds to the transistor PM. In an example, the conductive pattern 455 itself is the word line WLp and extends continuously along multiple memory cells in a memory row. In a further example, the conductive pattern 455 is electrically coupled to the word line WLp at a metal layer higher than the M0 layer in the redistribution structure 460.

A metal layer, e.g., M0′ layer, between the transistors PM, NM comprises a conductive pattern 456 over and in electrical contact with the VG via 436. The conductive pattern 456 is a word line pattern configured as, or electrically coupled to, a word line WLn which corresponds to the transistor NM. In an example, the conductive pattern 456 itself is the word line WLn and extends continuously along multiple memory cells in a memory row. In a further example, the conductive pattern 456 is electrically coupled, by a conductive structure 457 comprising one or more metal layers and one or more via structures, to a conductive pattern 462 in a metal layer of the redistribution structure 460. In some embodiments, the conductive pattern 462 is the word line WLn which extends continuously along multiple memory cells in a memory row.

The example configuration in FIG. 4B corresponds to a memory cell described with respect to FIGS. 2A-2C where both the P-type and N-type transistors in each memory cell are electrically coupled to the corresponding word lines WLp, WLn through corresponding VG vias, such as VG vias 435, 436. When the CFET device in FIG. 4B is configured as a memory cell described with respect to FIGS. 3A-3C where the gate of one of the P-type and N-type transistors in each memory cell is electrically coupled to a corresponding power supply voltage, either the conductive pattern 455 is electrically coupled to a VDD power rail, or the conductive pattern 456 is electrically coupled to a VSS power rail.

FIG. 4C is a schematic cross-sectional view of a portion of a memory device 400C, in accordance with some embodiments. In some embodiments, the portion of the memory device 400C in FIG. 4C corresponds to the CFET device 400A and/or to the portion of the memory device 400B in FIG. 4B. For simplicity, corresponding components in FIGS. 4A-4C are designated by the same reference numerals.

The memory device 400C comprises VD vias 431-434 correspondingly over and in electrical contact with the MID contacts 421-424 of the transistors PM, NM. In the example configuration in FIG. 4C, the VD vias 432, 434 are physically arranged, along the Z axis, between the transistors PM, NM. Other configurations are within the scopes of various embodiments.

In the example configuration in FIG. 4B, the M0 layer comprises conductive patterns 451, 453 correspondingly over and in electrical contact with the VD vias 431, 433. The M0′ layer comprises conductive patterns 452, 454 correspondingly over and in electrical contact with the VD vias 432, 434. The conductive patterns 451, 452 are electrically coupled to correspondingly receive VDD and VSS. In some embodiments, at least one of the conductive patterns 451, 452 is a VDD or VSS power rail which extends continuously along multiple memory cells in a memory column or a memory row of a memory array of the memory device 400C.

The conductive patterns 453, 454 are bit line patterns configured as, or electrically coupled to, a bit line BL. In at least one embodiment, at least one of the conductive patterns 453, 454 extends continuously along multiple memory cells in a memory column of the memory array of the memory device 400C. The conductive patterns 453, 454 are electrically coupled to each other. For example, the conductive pattern 454 is electrically coupled, by a conductive structure 458 comprising one or more metal layers and one or more via structures, to a conductive pattern 464 in a metal layer of the redistribution structure 460. The conductive pattern 464 is further electrically coupled to the conductive pattern 453, by a conductive structure 459 comprising one or more metal layers and one or more via structures.

The example configuration in FIG. 4C corresponds to a memory cell described with respect to FIGS. 3A-3C where source/drains of the P-type and N-type transistors in each memory cell are electrically coupled to the bit line BL or to the corresponding VDD, VSS power rails. When the CFET device in FIG. 4C is configured as a memory cell described with respect to FIGS. 2A-2C where a source/drain of one of the P-type and N-type transistors in each memory cell is electrically floating, one of the VD vias 431, 432 is omitted. One or more advantages described herein are achievable by one or more of the CFET device 400A configured as a memory cell and/or the memory devices 400B, 400C.

FIG. 4D is a schematic perspective view of a planar configuration of semiconductor devices configurable as a memory cell, in accordance with some embodiments. The planar configuration in FIG. 4D is, in one or more embodiments, configurable as a memory cell 400D corresponding to one or more memory cells described with respect to FIGS. 1, 2A-2C, 3A-3C. For simplicity, corresponding components in FIGS. 4A-4D are designated by the same reference numerals.

Compared to the stacked configuration in FIG. 4A where the transistor PM and transistor NM are stacked on upon another and are arranged at different levels or layers with respect to the substrate 402, in the planar configuration in FIG. 4D, the transistor PM and transistor NM are arranged at the same level or layer with respect to the substrate 402. In the example configuration in FIG. 4D, the transistor PM and transistor NM are FinFETs or planar transistors in which the gates 415, 416 do not extend completely around the corresponding channels. In some embodiments, the transistor PM and transistor NM in the planar configuration are GAA transistors as described with respect to FIG. 4A. Likewise, in one or more embodiments, the transistor PM and transistor NM in a stacked configuration as described with respect to FIG. 4A are FinFETs or planar transistors. For electrically coupling the transistor PM and transistor NM in the planar configuration in FIG. 4D into a memory cell as described with respect to one or more of FIGS. 1, 2A-2C, 3A-3C, one or more VG vias, VD vias, conductive patterns and vias in a redistribution structure are formed. For example, one or more VG vias, VD vias, conductive patterns and vias are formed and/or arranged in manners similar to those described with respect to FIGS. 4B, 4C, with a difference in that the transistor PM and transistor NM are arranged at the same layer, rather than at different layers as in FIGS. 4B, 4C.

FIG. 4E includes schematic layout views of memory cells configured by semiconductor devices in various planar configurations, in accordance with some embodiments.

FIG. 4E shows a planar configuration 471 which comprises at least memory cells 473, 475 arranged in abutment along the Y axis. Each of the memory cells 473, 475 includes a P-type transistor (e.g., PMOS transistor) and an N-type transistor (e.g., NMOS transistor) arranged at the same layer as described with respect to FIG. 4D, with the NMOS transistor “above” the PMOS transistor when viewed along the Y axis. The planar configuration 471 is repeated along both the Y axis and X axis to configure a memory array.

FIG. 4E further shows a planar configuration 472 which comprises at least memory cells 474, 476 arranged in abutment along the Y axis. Each of the memory cells 474, 476 includes a PMOS transistor and an NMOS transistor arranged at the same layer as described with respect to FIG. 4D, with the PMOS transistor “above” the NMOS transistor when viewed along the Y axis. The planar configuration 472 is repeated along both the Y axis and X axis to configure a memory array. In some embodiments, the planar configurations 471, 472 are mixed in a memory array.

In a similar manner, the P-on-N configuration described with respect to FIGS. 4A-4C, or an N-on-P configuration, is repeated along both the X axis and Y axis to form a memory array. In some embodiments, the P-on-N configuration and N-on-P configuration are mixed in a memory array. One or more advantages described herein are achievable by memory cells and/or memory devices with one or more planar configurations described with respect to FIGS. 4D-4E.

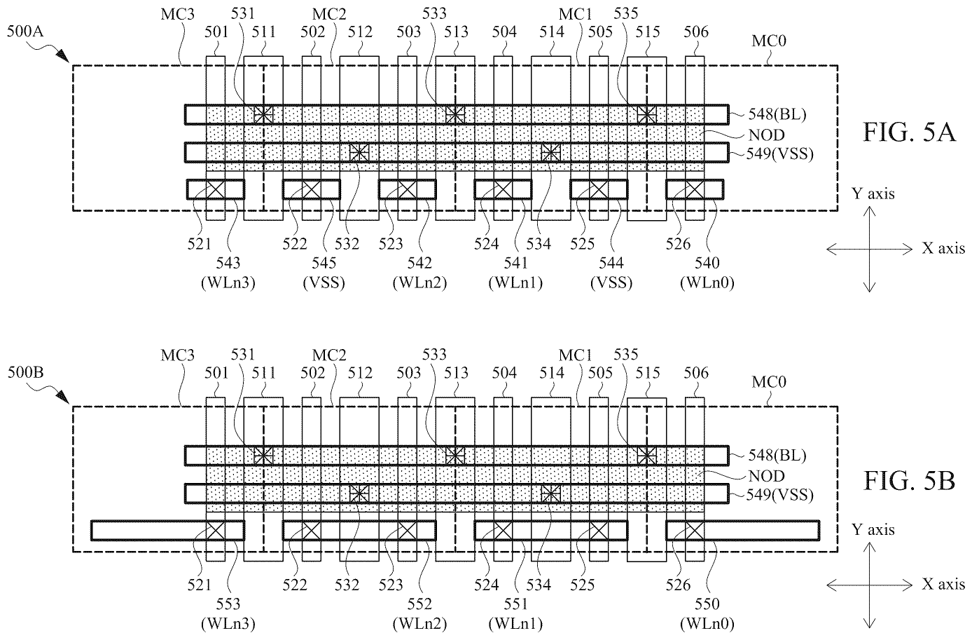

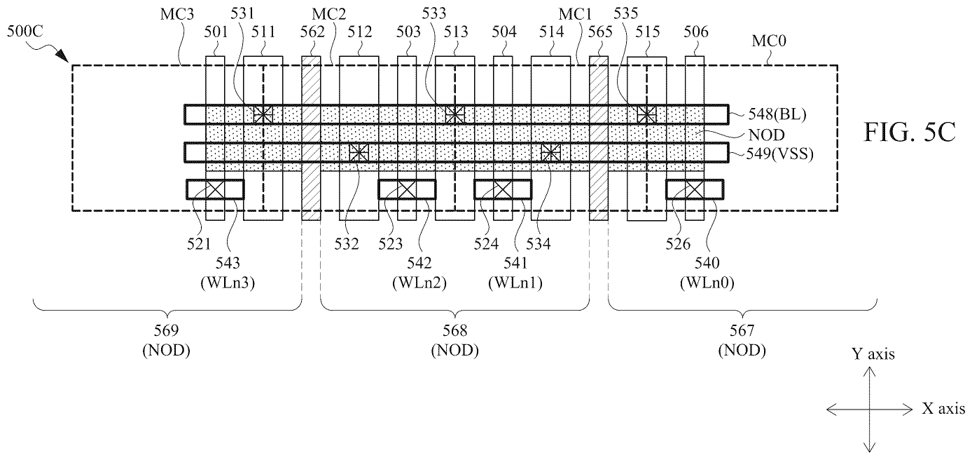

FIGS. 5A, 5B, 5C are schematic views of layouts 500A, 500B, 500C of semiconductor devices of a first type in various memory devices, in accordance with some embodiments. In the example configurations in FIGS. 5A-5C, the semiconductor devices are N-type transistors, e.g., NMOS transistors. In some embodiments, the layouts 500A, 500B, 500C correspond to N-type transistors in memory cells described with respect to one or more of FIGS. 1, 2A-2C, 3A-3C, 4A-4E. For simplicity, corresponding components in FIGS. 1, 2A-2C, 3A-3C, 4A-4E, 5A-5C are designated by the same reference numerals. In at least one embodiment, one or more of the layouts 500A, 500B, 500C, and/or layouts of one or more of memory cells in the layouts 500A, 500B, 500C, are stored in at least one standard cell library on at least one non-transitory computer-readable medium. The layouts 500A, 500B, 500C and modifications thereof are sometimes referred to as NMOS layouts.

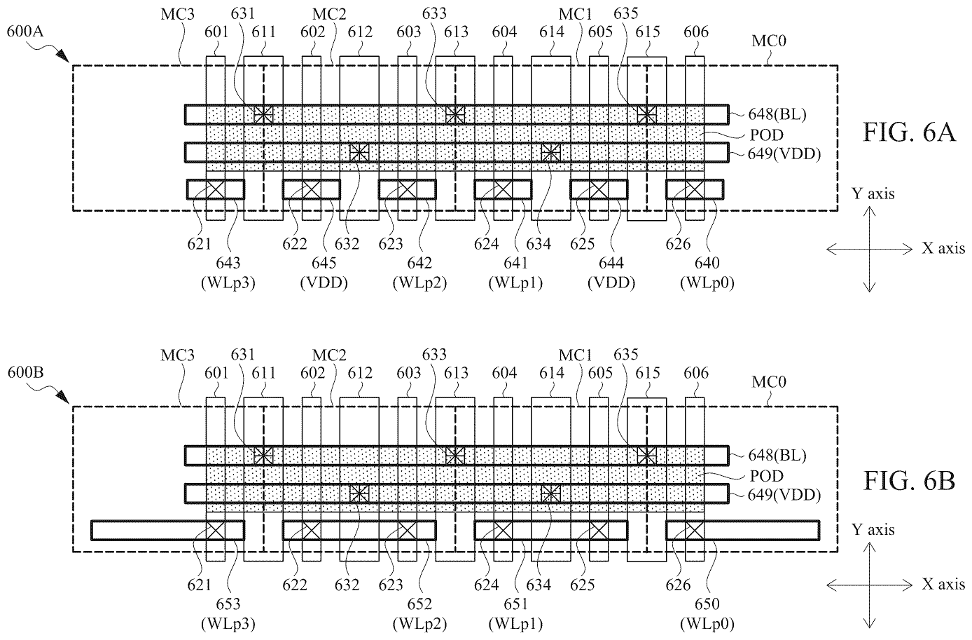

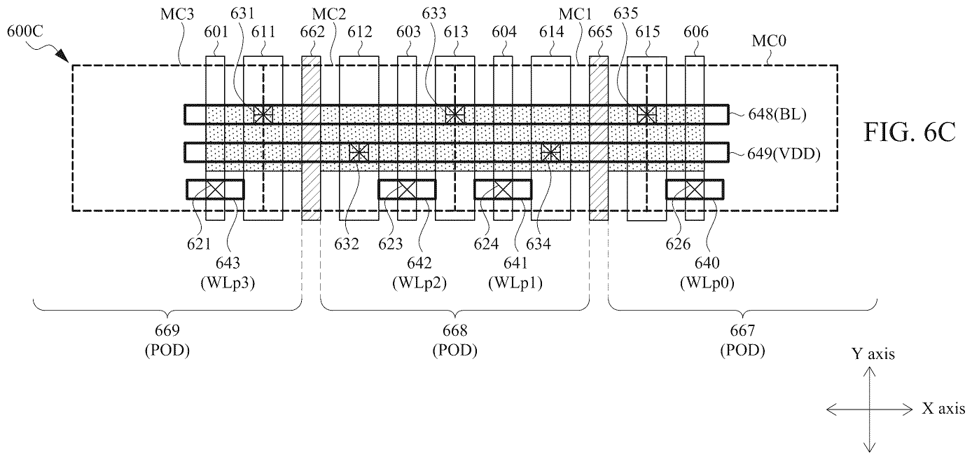

In FIG. 5A, the layout 500A comprises NMOS transistors in memory cells MC0-MC3 of a memory device corresponding to one or more memory devices described herein. The memory cells MC0-MC3 further comprise PMOS transistors, e.g., as described with respect to FIGS. 6A-6C. A boundary of each of the memory cells MC0-MC3 is shown in FIG. 5A. Various features in the memory cells MC0, MC3 are similar to those in the memory cells MC1, MC2, and are omitted for simplicity. Along the X axis, the boundaries of the adjacent memory cells, e.g., MC0 and MC1, MC1 and MC2, MC2 and MC3, abut each other.

The layout 500A comprises an NMOS active region NOD extending continuously along the X axis to configure source/drains and channels of the NMOS transistors in the memory cells MC0-MC3. The layout 500A further comprises gates or gate regions 501-506 extending along the Y axis across the active region NOD, and configuring together with the active region NOD, NMOS transistors for the memory cells MC0-MC3. For example, the NMOS transistor of the memory cell MC1 is configured by the active region NOD and the gate region 504, and the NMOS transistor of the memory cell MC2 is configured by the active region NOD and the gate region 503. The gate regions 503, 504 are examples of functional gate regions (or functional gates) which form transistors configured to perform a function in one or more operations of a memory device corresponding to the layout 500A. The NMOS transistor in each of the memory cells MC0-MC3 has one functional gate region (sometimes referred to as gate finger).

The gate regions 502, 505 also configure, together with the active region NOD, NMOS transistors which, however, are not included in the memory cells MC0-MC3. The NMOS transistors corresponding to the gate regions 505, 502 are electrically coupled to VSS as described herein, and are always turned OFF. The always-OFF NMOS transistor corresponding to the gate region 505 electrically isolates adjacent source/drains of the NMOS transistors in the adjacent memory cells MC0, MC1. The always-OFF NMOS transistor corresponding to the gate region 502 electrically isolates adjacent source/drains of the NMOS transistors in the adjacent memory cells MC2, MC3. The gate regions 502, 505 are examples of dummy gate regions (or dummy gates), because the corresponding NMOS transistors are not configured to perform a function in operations of a memory device corresponding to the layout 500A.

The layout 500A further comprises MD contacts 511-515 correspondingly over and in contact with source/drains in the active region NOD. For example, the MD contacts 513, 514 are correspondingly over and in contact with the source/drains of the NMOS transistor in the memory cell MC1, and the MID contacts 513, 513 are correspondingly over and in contact with the source/drains of the NMOS transistor in the memory cell MC2. The source/drain under the MID contact 513 and the MD contact 513 itself are common for the NMOS transistors in the memory cells MC1, MC2. Along the X axis, a pitch between adjacent MD contacts, e.g., a distance between center lines of the adjacent MD contacts, such as MD contacts 513, 514, is equal to a pitch (sometimes referred to as CPP) between adjacent gate regions., such as gate regions 502, 503. Generally, along the X axis, a transistor has a size of 1 T corresponding to 1 CPP between the MD contacts of the transistor. The NMOS transistor in each of the memory cells MC0-MC3 has a size of 1.5 T along the X axis. For example, the size of the NMOS transistor in the memory cell MC1 is the distance along the X axis between the center line of the dummy gate region 505 and the center line of the MID contact 513.

The layout 500A further comprises VG vias 521-526 correspondingly over and in electrical contact with the gate regions 501-506, and VD vias 531-535 correspondingly over and in electrical contact with the MID contacts 511-515. In the example configuration in FIG. 5A, all VG vias 521-526 do not overlap the active region NOD, in accordance with certain manufacturing requirements. Other configurations where VG vias overlap an underlying active region are within the scopes of various embodiments.

The layout 500A further comprises a metal layer over and in electrical contact with the VG, VD vias. In some embodiments where the layout 500A includes NMOS transistors as top semiconductor devices in a stacked configuration as described with respect to FIGS. 4A-4C, or NMOS transistors in a planar configuration as described with respect to FIGS. 4D-4E, the metal layer is an M0 layer. In at least one embodiment where the layout 500A includes NMOS transistors as bottom semiconductor devices in a stacked configuration as described with respect to FIGS. 4A-4C, the metal layer is an M0′ layer between the two layers of top and bottom semiconductor devices. For simplicity, the metal layer over and in electrical contact with the VG, VD vias is described herein as the M0 layer. A similar description is applicable to the M0′ layer.

The M0 layer comprises conductive patterns 540-545, 548, 549. The conductive patterns 540-543 are word line patterns corresponding to word lines WLn0-WLn3, and are correspondingly electrically coupled to the gate regions 506, 504, 503, 501 by the corresponding VG vias 526, 524, 523, 521. In some embodiments, the word line patterns 540-543 are correspondingly electrically coupled to the word lines WLn0-WLn3 in at least one metal layer higher than the M0 layer in a redistribution structure, as described herein. The conductive patterns 544, 545 are VSS patterns and are correspondingly electrically coupled to the gate regions 505, 502 by the corresponding VG vias 525, 522. In some embodiments, the VSS patterns 544, 545 are electrically coupled to a VSS power rail. The conductive pattern 548 is a bit line pattern corresponding to a bit line BL, and extends continuously along the X axis over multiple memory cells MC0-MC3. In at least one embodiment, the memory cells MC0-MC3 are memory cells in a memory column. The bit line pattern 548 is electrically coupled to the underlying MD contacts 511, 513, 515 by the corresponding VD vias 531, 533, 535. The conductive pattern 549 is a VSS power rail which extends continuously along the X axis over multiple memory cells MC0-MC3. The VSS power rail 549 is electrically coupled to the underlying MD contacts 512, 514 by the corresponding VD vias 532, 534.

The layout 500A is an example configuration with various possible electrical connections one or more of which are omittable or modifiable to configure memory cells in accordance with some embodiments. For example, the configurations as shown for memory cells MC1, MC2 in the layout 500A correspond to the transistor N20 in the memory device 200 or the transistor N30 in the memory device 300. To configure the NMOS transistor in the memory cell MC1 as the transistor N21 in the memory device 200, the VD via 534 is omitted, so that the source/drain under the MD contact 514 is electrically isolated from the overlying VSS power rail 549 and becomes floating. To configure the NMOS transistor in the memory cell MC1 as the transistor N31 in the memory device 300, the conductive pattern 541 is configured as a VSS pattern electrically coupled to a VSS power rail, instead of the corresponding word line WLn1.

In FIG. 5B, the layout 500B is similar to the layout 500A, but differs from the layout 500A in the size and number of gate fingers of the NMOS transistor in each memory cell. Specifically, the NMOS transistor in each of the memory cells MC0-MC3 in the layout 500B has a size of 2 T along the X axis, and includes two gate fingers.

In the layout 500B, the gate regions 502, 505 are functional gate regions, instead of dummy gate regions as in the layout 500A. In the memory cell MC1, the gate regions 504, 505 are both electrically coupled by corresponding VG vias 524, 525 to a conductive pattern 551 which is a word line pattern corresponding to the word line WLn1. The word line pattern 551 is elongated along the X axis, bridges the gate regions 504, 505, and replaces conductive patterns 541, 544 of the layout 500A. The layout 500B further comprises similar elongated word line patterns 550, 552, 553 corresponding to the word lines WLn0, WLn2, WLn3. Because the gate regions 504, 505 are electrically coupled together, they are configured to form with the active region NOD a single NMOS transistor for the memory cell MC1. The single NMOS transistor has two gate fingers corresponding to the gate regions 504, 505. The size of the NMOS transistor in the memory cell MC1 along the X axis is a distance between the center lines of the MD contacts 513, 515, i.e., 2 CPP or 2 T. In some embodiments, although the memory cells in the layouts 500A, 500B have NMOS transistors with different sizes (i.e., 1.5 T or 2 T), the same number of memory cells in the layouts 500A, 500B occupies the same area.

The layout 500B is an example configuration with various possible electrical connections one or more of which are omittable or modifiable to configure memory cells in accordance with some embodiments. For example, the configurations as shown for memory cells MC1, MC2 in the layout 500B correspond to the transistor N20 in the memory device 200 or the transistor N30 in the memory device 300. To configure the NMOS transistor in the memory cell MC1 as the transistor N21 in the memory device 200, the VD via 534 is omitted, so that the source/drain under the MD contact 514 is electrically isolated from the overlying VSS power rail 549 and becomes floating. To configure the NMOS transistor in the memory cell MC1 as the transistor N31 in the memory device 300, the conductive pattern 551 is configured as a VSS pattern electrically coupled to a VSS power rail, instead of the corresponding word line WLn1.

In FIG. 5C, the layout 500C is similar to the layout 500A, but differs from the layout 500A in continuity of the active region NOD.

Specifically, in the layout 500A, the active region NOD extends continuously through memory cells MC0-MC3, and certain adjacent source/drains are electrically isolated from each other by a dummy gate region, e.g., the gate regions 502, 505, electrically coupled to VSS. In the layout 500C, the active region NOD is discontinuous, and includes several segments 567, 568, 569 physically disconnected from each other by isolation structures 562, 565. The isolation structures 562, 565 correspondingly replace the dummy gate regions 502, 505 of the layout 500A, and are configured to perform the same function as the dummy gate regions 502, 505, i.e., electrically isolating certain adjacent source/drains. The VSS patterns 544, 545 of the layout 500A are also omitted from the layout 500C. Like the layout 500A, the layout 500C has, in each memory cell, an NMOS transistor with a size of 1.5 T and one gate finger, and occupies the same area as the layout 500B.

The layout 500C is an example configuration with various possible electrical connections one or more of which are omittable or modifiable to configure memory cells in accordance with some embodiments. For example, the configurations as shown for memory cells MC1, MC2 in the layout 500C correspond to the transistor N20 in the memory device 200 or the transistor N30 in the memory device 300. To configure the NMOS transistor in the memory cell MC1 as the transistor N21 in the memory device 200, the VD via 534 is omitted, so that the source/drain under the MID contact 514 is electrically isolated from the overlying VSS power rail 549 and becomes floating. To configure the NMOS transistor in the memory cell MC1 as the transistor N31 in the memory device 300, the conductive pattern 541 is configured as a VSS pattern electrically coupled to a VSS power rail, instead of the corresponding word line WLn1.

Compared to the layouts 500A, 500C, the layout 500B includes a higher number of gate fingers per memory cell which provides higher speed, but also consumes more power, in some embodiments. In at least one embodiment, the layout 500B is selected where performance is a design consideration. In situations where NMOS transistors have large turn-ON currents, the layouts 500A, 500C with the smaller NMOS transistor size reduce the word line front loading and permit word line drivers to be smaller to save the chip area. In at least one embodiment, the layout 500A or layout 500C is selected where chip area or power consumption is a design consideration. One or more advantages described herein are achievable by memory devices corresponding to one or more of the layouts 500A, 500B, 500C.

FIGS. 6A, 6B, 6C are schematic views of layouts 600A, 600B, 600C of semiconductor devices of a second type in various memory devices, in accordance with some embodiments. In the example configurations in FIGS. 6A-6C, the semiconductor devices are P-type transistors, e.g., PMOS transistors. In some embodiments, the layouts 600A, 600B, 600C correspond to P-type transistors in memory cells described with respect to one or more of FIGS. 1, 2A-2C, 3A-3C, 4A-4E. For simplicity, corresponding components in FIGS. 1, 2A-2C, 3A-3C, 4A-4E, 5A-5C, 6A-6C are designated by the same reference numerals. In at least one embodiment, one or more of the layouts 600A, 600B, 600C, and/or layouts of one or more of memory cells in the layouts 600A, 600B, 600C, are stored in at least one standard cell library on at least one non-transitory computer-readable medium. The layouts 600A, 600B, 600C and modifications thereof are sometimes referred to as PMOS layouts.

In FIG. 6A, the layout 600A comprises PMOS transistors in memory cells MC0-MC3 of a memory device corresponding to one or more memory devices described herein. The memory cells MC0-MC3 further comprise NMOS transistors, e.g., as described with respect to FIGS. 5A-5C. A boundary of each of the memory cells MC0-MC3 is shown in FIG. 6A. Various features in the memory cells MC0, MC3 are similar to those in the memory cells MC1, MC2, and are omitted for simplicity. Along the X axis, the boundaries of the adjacent memory cells abut each other.

The layout 600A comprises a PMOS active region POD extending continuously along the X axis to configure source/drains and channels of the PMOS transistors in the memory cells MC0-MC3. The layout 600A further comprises gates or gate regions 601-606 extending along the Y axis across the active region POD, and configuring together with the active region POD, PMOS transistors for the memory cells MC0-MC3. For example, the PMOS transistor of the memory cell MC1 is configured by the active region POD and the gate region 604, and the PMOS transistor of the memory cell MC2 is configured by the active region POD and the gate region 603. The gate regions 603, 604 are examples of functional gate regions. The PMOS transistor in each of the memory cells MC0-MC3 has one functional gate region (or one gate finger).

The gate regions 602, 605 also configure, together with the active region POD, PMOS transistors which, however, are not included in the memory cells MC0-MC3. The PMOS transistors corresponding to the gate regions 605, 602 are electrically coupled to VDD as described herein, and are always turned OFF. The always-OFF PMOS transistor corresponding to the gate region 605 electrically isolates adjacent source/drains of the PMOS transistors in the adjacent memory cells MC0, MC1. The always-OFF PMOS transistor corresponding to the gate region 602 electrically isolates adjacent source/drains of the PMOS transistors in the adjacent memory cells MC2, MC3. The gate regions 602, 605 are examples of dummy gate regions (or dummy gates).

The layout 600A further comprises MD contacts 611-615 correspondingly over and in contact with source/drains in the active region POD. For example, the MD contacts 613, 614 are correspondingly over and in contact with the source/drains of the PMOS transistor in the memory cell MC1, and the MD contacts 613, 613 are correspondingly over and in contact with the source/drains of the PMOS transistor in the memory cell MC2. The source/drain under the MD contact 613 and the MD contact 613 itself are common for the PMOS transistors in the memory cells MC1, MC2. Along the X axis, a pitch between adjacent MD contacts, e.g., a distance between center lines of the adjacent MD contacts, such as MD contacts 613, 614, is equal to a pitch (sometimes referred to as CPP) between adjacent gate regions, such as gate regions 602, 603. The PMOS transistor in each of the memory cells MC0-MC3 has a size of 1.5 T along the X axis. For example, the size of the PMOS transistor in the memory cell MC1 is the distance along the X axis between the center line of the MID contact 615 and the center line of the MID contact 613.

The layout 600A further comprises VG vias 621-626 correspondingly over and in electrical contact with the gate regions 601-606, and VD vias 631-635 correspondingly over and in electrical contact with the MD contacts 611-615. In the example configuration in FIG. 6A, all VG vias 621-626 do not overlap the active region POD, in accordance with certain manufacturing requirements. Other configurations where VG vias overlap an underlying active region are within the scopes of various embodiments.

The layout 600A further comprises a metal layer over and in electrical contact with the VG, VD vias. In some embodiments where the layout 600A includes PMOS transistors as top semiconductor devices in a stacked configuration as described with respect to FIGS. 4A-4C, or PMOS transistors in a planar configuration as described with respect to FIGS. 4D-4E, the metal layer is an M0 layer. In at least one embodiment where the layout 600A includes PMOS transistors as bottom semiconductor devices in a stacked configuration as described with respect to FIGS. 4A-4C, the metal layer is an M0′ layer between the two layers of top and bottom semiconductor devices. For simplicity, the metal layer over and in electrical contact with the VG, VD vias is described herein as the M0 layer. A similar description is applicable to the M0′ layer.

The M0 layer comprises conductive patterns 640-645, 648, 649. The conductive patterns 640-643 are word line patterns corresponding to word lines WLp0-WLp3, and are correspondingly electrically coupled to the gate regions 606, 604, 603, 601 by the corresponding VG vias 626, 624, 623, 621. In some embodiments, the word line patterns 640-643 are correspondingly electrically coupled to the word lines WLp0-WLp3 in at least one metal layer higher than the M0 layer in a redistribution structure, as described herein. The conductive patterns 644, 645 are VDD patterns and are correspondingly electrically coupled to the gate regions 605, 602 by the corresponding VG vias 625, 622. In some embodiments, the VDD patterns 644, 645 are electrically coupled to a VDD power rail. The conductive pattern 648 is a bit line pattern corresponding to a bit line BL, and extends continuously along the X axis over multiple memory cells MC0-MC3. In at least one embodiment, the memory cells MC0-MC3 are memory cells in a memory column. The bit line pattern 648 is electrically coupled to the underlying MD contacts 611, 613, 615 by the corresponding VD vias 631, 633, 635. The conductive pattern 649 is a VDD power rail which extends continuously along the X axis over multiple memory cells MC0-MC3. The VDD power rail 649 is electrically coupled to the underlying MD contacts 612, 614 by the corresponding VD vias 632, 634.

The layout 600A is an example configuration with various possible electrical connections one or more of which are omittable or modifiable to configure memory cells in accordance with some embodiments. For example, the configurations as shown for memory cells MC1, MC2 in the layout 600A correspond to the transistor P21 in the memory device 200 or the transistor P31 in the memory device 300. To configure the PMOS transistor in the memory cell MC1 as the transistor P20 in the memory device 200, the VD via 634 is omitted, so that the source/drain under the MID contact 614 is electrically isolated from the overlying VDD power rail 649 and becomes floating. To configure the PMOS transistor in the memory cell MC1 as the transistor P30 in the memory device 300, the conductive pattern 641 is configured as a VDD pattern electrically coupled to a VDD power rail, instead of the corresponding word line WLp1.

In FIG. 6B, the layout 600B is similar to the layout 600A, but differs from the layout 600A in the size and number of gate fingers of the PMOS transistor in each memory cell.

Specifically, the PMOS transistor in each of the memory cells MC0-MC3 in the layout 600B has a size of 2 T along the X axis, and includes two gate fingers.

In the layout 600B, the gate regions 602, 605 are functional gate regions, instead of dummy gate regions as in the layout 600A. In the memory cell MC1, the gate regions 604, 605 are both electrically coupled by corresponding VG vias 624, 625 to a conductive pattern 651 which is a word line pattern corresponding to the word line WLp1. The word line pattern 651 is elongated along the X axis, bridges the gate regions 604, 605, and replaces conductive patterns 641, 644 of the layout 600A. The layout 600B further comprises similar elongated word line patterns 650, 652, 653 corresponding to the word lines WLp0, WLp2, WLp3. Because the gate regions 604, 605 are electrically coupled together, they are configured to form with the active region POD a single PMOS transistor for the memory cell MC1. The single PMOS transistor has two gate fingers corresponding to the gate regions 604, 605. The size of the PMOS transistor in the memory cell MC1 along the X axis is a distance between the center lines of the MID contacts 613, 615, i.e., 2 CPP or 2 T. In some embodiments, although the memory cells in the layouts 500A, 500B, 600A, 600B have NMOS or PMOS transistors with different sizes (1.5 T or 2 T), the same number of memory cells in the layouts 500A, 500B, 600A, 600B occupies the same area.

The layout 600B is an example configuration with various possible electrical connections one or more of which are omittable or modifiable to configure memory cells in accordance with some embodiments. For example, the configurations as shown for memory cells MC1, MC2 in the layout 600B correspond to the transistor P21 in the memory device 200 or the transistor P31 in the memory device 300. To configure the PMOS transistor in the memory cell MC1 as the transistor P20 in the memory device 200, the VD via 634 is omitted, so that the source/drain under the MD contact 614 is electrically isolated from the overlying VDD power rail 649 and becomes floating. To configure the PMOS transistor in the memory cell MC1 as the transistor P30 in the memory device 300, the conductive pattern 651 is configured as a VDD pattern electrically coupled to a VDD power rail, instead of the corresponding word line WLp1.

In FIG. 6C, the layout 600C is similar to the layout 600A, but differs from the layout 600A in continuity of the active region POD.

Specifically, in the layout 600A, the active region POD extends continuously through memory cells MC0-MC3, and certain adjacent source/drains are electrically isolated from each other by a dummy gate region, e.g., the gate regions 602, 605, electrically coupled to VDD. In the layout 600C, the active region POD is discontinuous, and includes several segments 667, 668, 669 physically disconnected from each other by isolation structures 662, 665. The isolation structures 662, 665 correspondingly replace the dummy gate regions 602, 605 of the layout 600A, and are configured to perform the same function as the dummy gate regions 602, 605, i.e., electrically isolating certain adjacent source/drains. The VDD patterns 644, 645 of the layout 600A are also omitted from the layout 600C. Like the layout 600A, the layout 600C has, in each memory cell, a PMOS transistor with a size of 1.5 T and one gate finger, and occupies the same area as the layout 600B.

The layout 600C is an example configuration with various possible electrical connections one or more of which are omittable or modifiable to configure memory cells in accordance with some embodiments. For example, the configurations as shown for memory cells MC1, MC2 in the layout 600C correspond to the transistor P21 in the memory device 200 or the transistor P31 in the memory device 300. To configure the PMOS transistor in the memory cell MC1 as the transistor P20 in the memory device 200, the VD via 634 is omitted, so that the source/drain under the MD contact 614 is electrically isolated from the overlying VDD power rail 649 and becomes floating. To configure the PMOS transistor in the memory cell MC1 as the transistor P30 in the memory device 300, the conductive pattern 641 is configured as a VDD pattern electrically coupled to a VDD power rail, instead of the corresponding word line WLp1.

Compared to the layouts 600A, 600C, the layout 600B includes a higher number of gate fingers per memory cell which provides higher speed, but also consumes more power, in some embodiments. In at least one embodiment, the layout 600B is selected where performance is a design consideration. In situations where PMOS transistors have large turn-ON currents, the layouts 600A, 600C with the smaller PMOS transistor size reduce the word line front loading and permit word line drivers to be smaller to save the chip area. In at least one embodiment, the layout 600A or layout 600C is selected where chip area or power consumption is a design consideration. One or more advantages described herein are achievable by memory devices corresponding to one or more of the layouts 600A, 600B, 600C.

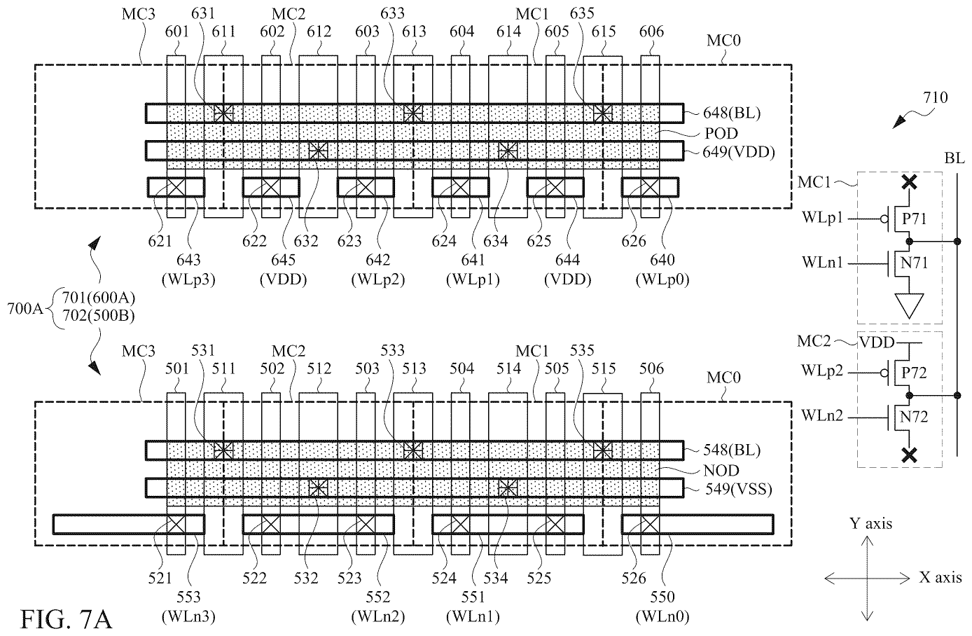

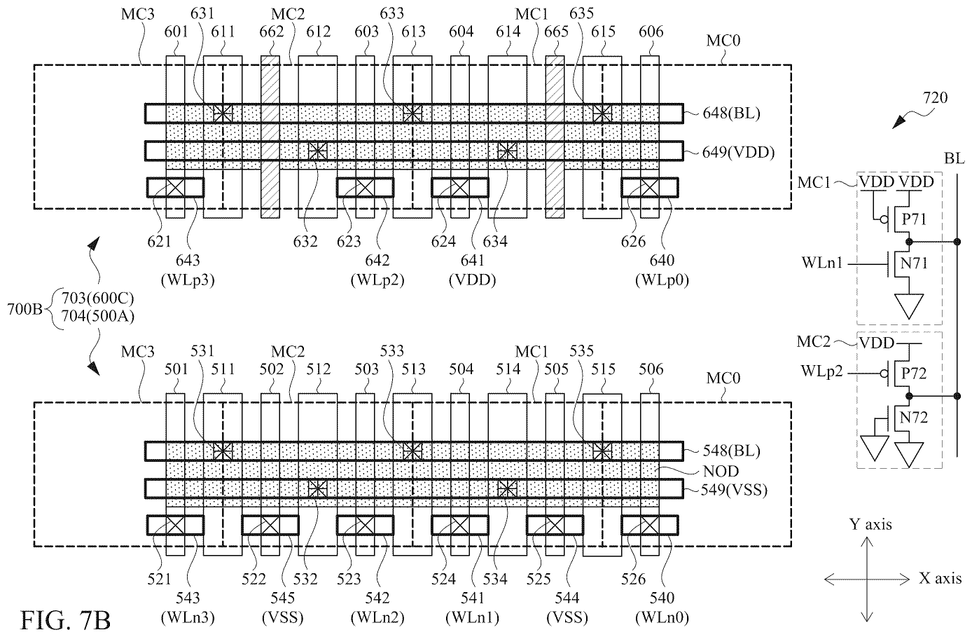

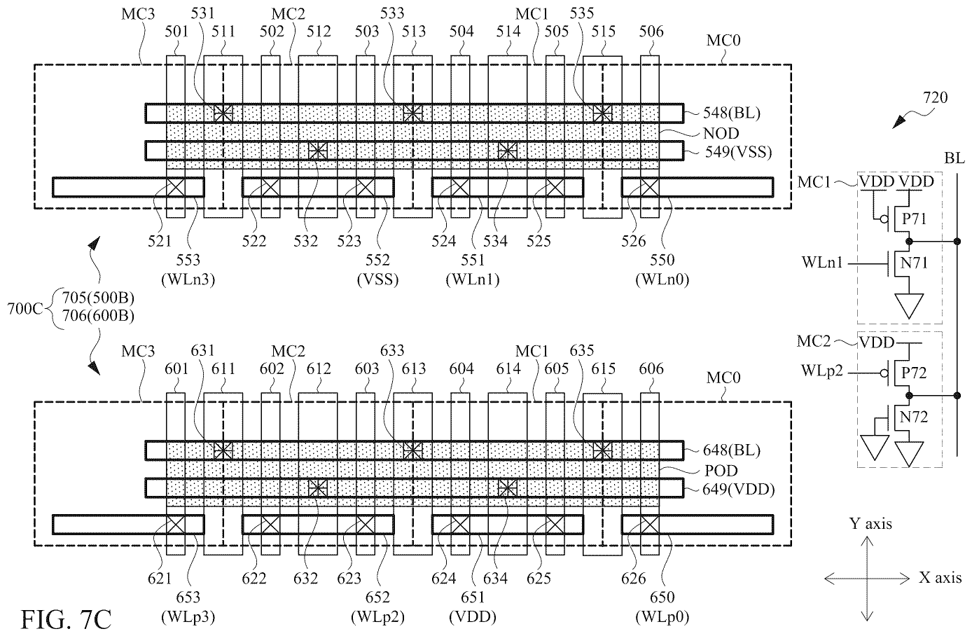

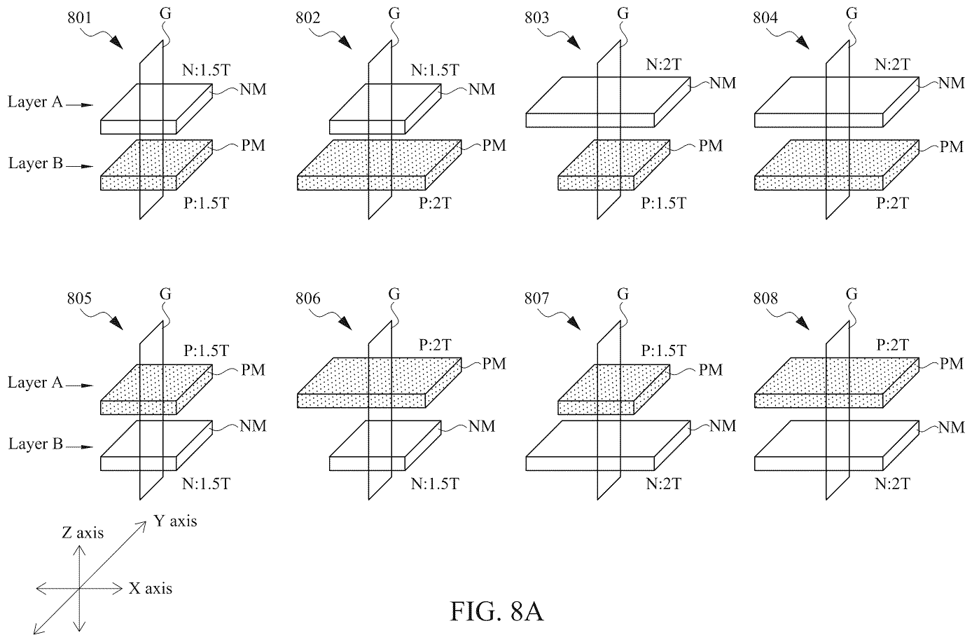

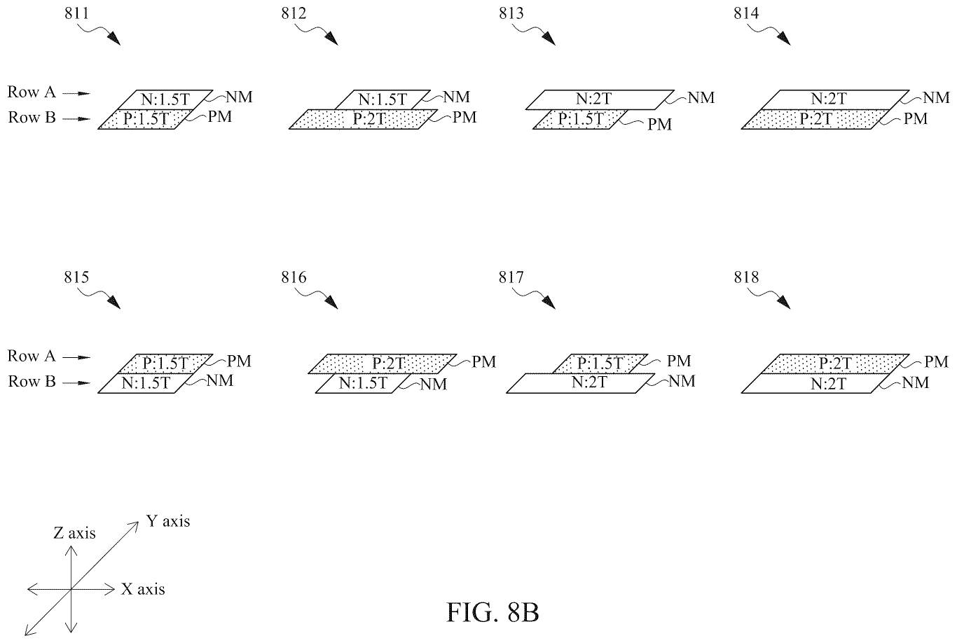

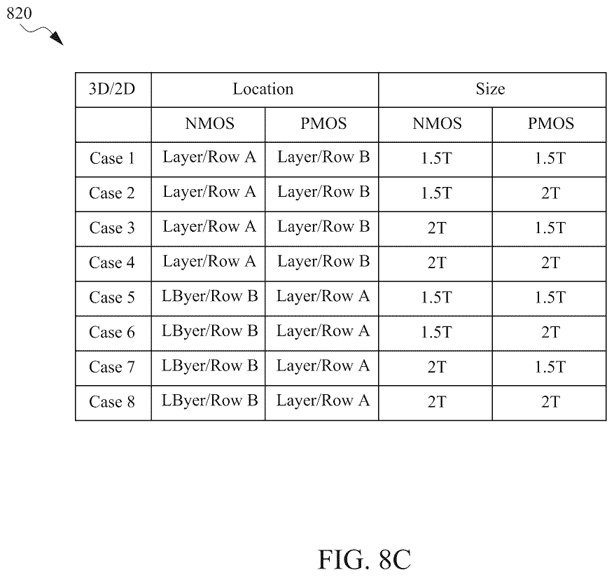

In some embodiments, any NMOS layout described herein, e.g., with respect to FIGS. 5A-5C, is combinable with any PMOS layout described herein, e.g., with respect to FIGS. 6A-6C, to configure a memory device. In at least one embodiment, where a memory device has a stacked configuration as described with respect to FIGS. 4A-4C, any NMOS layout described herein is applicable to any one of the top layer and the bottom layer, and any PMOS layout described herein is applicable to the other of the top layer and the bottom layer. In at least one embodiment, where a memory device has a planar configuration as described with respect to FIGS. 4D-4E, any NMOS layout described herein is applicable to NMOS transistors in any of the planar configurations 471, 472, and any PMOS layout described herein is applicable to PMOS transistors in any of the planar configurations 471, 472. Several non-limiting examples of an NMOS layout in combination with a PMOS layout to configure a memory device are described with respect to FIGS. 7A-7C, 8A-8C.

FIG. 7A includes a schematic circuit diagram and a schematic view of a layout of a portion of a memory device 700A, in accordance with some embodiments. In some embodiments, the memory device 700A corresponds to one or more memory devices described herein, and/or includes one or more memory cells described herein. For simplicity, corresponding components in FIGS. 1, 2A-2C, 3A-3C, 4A-4E, 5A-5C, 6A-6C, 7A-7C are designated by the same reference numerals.

A schematic circuit diagram 710 of the portion of the memory device 700A in FIG. 7A includes memory cells MC1, MC2 configured similarly to the memory cells MC20, MC21 in the memory device 200. The layout of the memory device 700A in FIG. 7A includes a PMOS layout 701 for PMOS transistors of the memory device 700A, and an NMOS layout 702 for the NMOS transistors of the memory device 700A.

The PMOS layout 701 shows PMOS transistors P71, P72 of the memory cells MC1, MC2. The PMOS layout 701 is similar to the layout 600A, with a difference in that the VD via 634 of the IC layout 600A is omitted to configure the PMOS transistor P71 with a floating second source/drain.

The NMOS layout 702 shows NMOS transistors N71, N72 of the memory cells MC1, MC2. The NMOS layout 702 is similar to the layout 500B, with a difference in that the VD via 532 of the IC layout 500B is omitted to configure the NMOS transistor N72 with a floating second source/drain.

The boundaries of the memory cells MC0-MC3 in the PMOS layout 701 correspondingly coincide with the boundaries of the memory cells MC0-MC3 in the NMOS layout 702. Along the Y axis and/or the Z axis, the gate regions 501-506 and MD contacts 511-515 are correspondingly aligned with the gate regions 601-606 and MID contacts 611-615. The bit line patterns 548, 648 are electrically coupled to each other. The layout in FIG. 7A is an example layout including memory cells each of which has a 1.5 T PMOS transistor and a 2 T NMOS transistor.

FIG. 7B includes a schematic circuit diagram and a schematic view of a layout of a portion of a memory device 700B, in accordance with some embodiments. In some embodiments, the memory device 700B corresponds to one or more memory devices described herein, and/or includes one or more memory cells described herein.

A schematic circuit diagram 720 of the portion of the memory device 700B in FIG. 7B includes memory cells MC1, MC2 configured similarly to the memory cells MC30, MC31 in the memory device 300. The layout of the memory device 700B in FIG. 7B includes a PMOS layout 703 for PMOS transistors of the memory device 700B, and an NMOS layout 704 for the NMOS transistors of the memory device 700B.

The PMOS layout 703 shows PMOS transistors P71, P72 of the memory cells MC1, MC2. The PMOS layout 703 is similar to the layout 600C, with a difference in that the conductive pattern 641 is configured as a VDD pattern electrically coupled to a VDD power rail, instead of the corresponding word line WLp1, to configure the PMOS transistor P71 to be in the always-OFF state.

The NMOS layout 704 shows NMOS transistors N71, N72 of the memory cells MC1, MC2. The NMOS layout 704 is similar to the layout 500A, with a difference in that the conductive pattern 542 is configured as a VSS pattern electrically coupled to a VSS power rail, instead of the corresponding word line WLn2, to configure the NMOS transistor N72 to be in the always-OFF state.

The boundaries of the memory cells MC0-MC3 in the PMOS layout 703 correspondingly coincide with the boundaries of the memory cells MC0-MC3 in the NMOS layout 704. Along the Y axis and/or the Z axis, the gate regions 501-506 and MID contacts 511-515 are correspondingly aligned with the gate region 601, isolation structure 662, gate regions 603, 604, isolation structure 665, gate region 606 and MD contacts 611-615. The bit line patterns 548, 648 are electrically coupled to each other. The layout in FIG. 7B is an example layout including memory cells each of which has a 1.5 T PMOS transistor and a 1.5 T NMOS transistor. The layout in FIG. 7B is also an example layout including both a discontinuous active region (in the PMOS layout 703) and a continuous active region (in the NMOS layout 704).

FIG. 7C includes a schematic circuit diagram and a schematic view of a layout of a portion of a memory device 700C, in accordance with some embodiments. In some embodiments, the memory device 700C corresponds to one or more memory devices described herein, and/or includes one or more memory cells described herein.

The schematic circuit diagram 720 of the portion of the memory device 700C in FIG. 7C includes memory cells MC1, MC2 configured similarly to the memory cells MC30, MC31 in the memory device 300. The layout of the memory device 700C in FIG. 7C includes a PMOS layout 706 for PMOS transistors of the memory device 700C, and an NMOS layout 705 for the NMOS transistors of the memory device 700C.

The PMOS layout 706 shows PMOS transistors P71, P72 of the memory cells MC1, MC2. The PMOS layout 706 is similar to the layout 600B, with a difference in that the conductive pattern 651 is configured as a VDD pattern electrically coupled to a VDD power rail, instead of the corresponding word line WLp1, to configure the PMOS transistor P71 to be in the always-OFF state.

The NMOS layout 705 shows NMOS transistors N71, N72 of the memory cells MC1, MC2. The NMOS layout 705 is similar to the layout 500B, with a difference in that the conductive pattern 552 is configured as a VSS pattern electrically coupled to a VSS power rail, instead of the corresponding word line WLn2, to configure the NMOS transistor N72 to be in the always-OFF state.

The boundaries of the memory cells MC0-MC3 in the PMOS layout 706 correspondingly coincide with the boundaries of the memory cells MC0-MC3 in the NMOS layout 705. Along the Y axis and/or the Z axis, the gate regions 501-506 and MD contacts 511-515 are correspondingly aligned with the gate regions 601-606 and MID contacts 611-615. The bit line patterns 548, 648 are electrically coupled to each other. The layout in FIG. 7C is an example layout including memory cells each of which has a 2 T PMOS transistor and a 2 T NMOS transistor. One or more advantages described herein are achievable by one or more of the memory devices 700A, 700B, 700C.

FIG. 8A includes schematic perspective views of various memory cells 801-808 configured by semiconductor devices in a stacked configuration, in accordance with some embodiments. In some embodiments, each of the memory cells 801-808 corresponds to one or more memory cells described with respect to FIGS. 1, 2A-2C, 3A-3C, 4A-4C, 5A-5C, 6A-6C, 7A-7C.

Each of the memory cells 801-808 comprises a P-type transistor PM and an N-type transistor NM represented by their corresponding active regions in FIG. 8A. In the memory cells 801-804, the transistor NM is at the upper layer (Layer A) and the transistor PM is at the lower layer (Layer B). In the memory cells 805-808, the transistor PM is at the upper layer (Layer A) and the transistor NM is at the lower layer (Layer B). Gates of the transistor PM and transistor NM in each of memory cells 801-808 are commonly designated as G. A size and type of each of the transistor PM and transistor NM are indicated for each of the memory cells 801-808.

For example, in the memory cell 801, the transistor NM is at Layer A and has a size of 1.5 T as described with respect to FIGS. 5A, 5C, whereas the transistor PM is at Layer B and has a size of 1.5 T as described with respect to FIGS. 6A, 6C.

For a further example, in the memory cell 804, the transistor NM is at Layer A and has a size of 2 T as described with respect to FIG. 5B, whereas the transistor PM is at Layer B and has a size of 2 T as described with respect to FIG. 6B. In some embodiments, the memory cell 804 corresponds to one or more memory cells described with respect to FIG. 7C.

For a further example, in the memory cell 805, the transistor PM is at Layer A and has a size of 1.5 T as described with respect to FIGS. 6A, 6C, whereas the transistor NM is at Layer B and has a size of 1.5 T as described with respect to FIGS. 5A, 5C. In some embodiments, the memory cell 805 corresponds to one or more memory cells described with respect to FIG. 7B.

For a further example, in the memory cell 807, the transistor PM is at Layer A and has a size of 1.5 T as described with respect to FIGS. 6A, 6C, whereas the transistor NM is at Layer B and has a size of 2 T as described with respect to FIG. 5B. In some embodiments, the memory cell 807 corresponds to one or more memory cells described with respect to FIG. 7A. One or more advantages described herein are achievable by one or more of memory devices including one or more of the memory cells 801-808.

FIG. 8B includes schematic perspective views of various memory cells 811-818 configured by semiconductor devices in a planar configuration, in accordance with some embodiments. In some embodiments, each of the memory cells 811-818 corresponds to one or more memory cells described with respect to FIGS. 1, 2A-2C, 3A-3C, 4D-4E, 5A-5C, 6A-6C, 7A-7C.

Each of the memory cells 811-818 comprises a P-type transistor PM and an N-type transistor NM represented by their corresponding active regions in FIG. 8B. In the memory cells 811-814, the transistor NM is in Row A “above” (along the Y axis) the transistor PM in Row B. In some embodiments, the memory cells 811-814 correspond to memory cells in the planar configuration 471 described with respect to FIG. 4E. In the memory cells 815-818, the transistor PM is in Row A “above” (along the Y axis) the transistor NM in Row B. In some embodiments, the memory cells 815-818 correspond to memory cells in the planar configuration 472 described with respect to FIG. 4E. Gates of the transistor PM and transistor NM are omitted in FIG. 8B. A size and type of each of the transistor PM and transistor NM are indicated for each of the memory cells 811-818.

For example, in the memory cell 811, the transistor NM is at Row A and has a size of 1.5 T as described with respect to FIGS. 5A, 5C, whereas the transistor PM is at Row B and has a size of 1.5 T as described with respect to FIGS. 6A, 6C.

For a further example, in the memory cell 814, the transistor NM is at Row A and has a size of 2 T as described with respect to FIG. 5B, whereas the transistor PM is at Row B and has a size of 2 T as described with respect to FIG. 6B. In some embodiments, the memory cell 814 corresponds to one or more memory cells described with respect to FIG. 7C.

For a further example, in the memory cell 815, the transistor PM is at Row A and has a size of 1.5 T as described with respect to FIGS. 6A, 6C, whereas the transistor NM is at Row B and has a size of 1.5 T as described with respect to FIGS. 5A, 5C. In some embodiments, the memory cell 815 corresponds to one or more memory cells described with respect to FIG. 7B.

For a further example, in the memory cell 817, the transistor PM is at Row A and has a size of 1.5 T as described with respect to FIGS. 6A, 6C, whereas the transistor NM is at Row B and has a size of 2 T as described with respect to FIG. 5B. In some embodiments, the memory cell 817 corresponds to one or more memory cells described with respect to FIG. 7A. One or more advantages described herein are achievable by one or more of memory devices including one or more of the memory cells 811-818.

FIG. 8C is a table 820 summarizing various memory cell configurations, in accordance with some embodiments. In some embodiments, the memory cell configurations in the table 820 correspond to one or more memory cells described herein.

In the Table 820, Cases 1-8 are commonly indicated for both stacked configurations (3D) and planar configurations (2D). Locations of the NMOS transistor and the PMOS transistor in each memory cell are indicated as at Layer A, Row A, Layer B, Row B as described with respect to FIGS. 8A, 8B. Sizes of the NMOS transistor and the PMOS transistor in each memory cell are also indicated as 1.5 T or 2 T. For example, Case 1 corresponds to the memory cells 801, 811, Case 2 corresponds to the memory cells 802, 812, Case 3 corresponds to the memory cells 803, 813, or the like. One or more advantages described herein are achievable by one or more of memory devices including memory cells corresponding to one or more of the memory cell configurations described with respect to FIG. 8C.

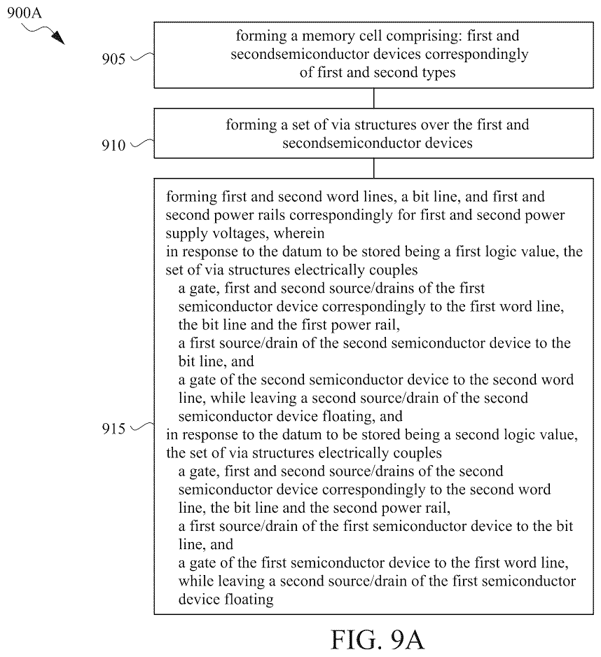

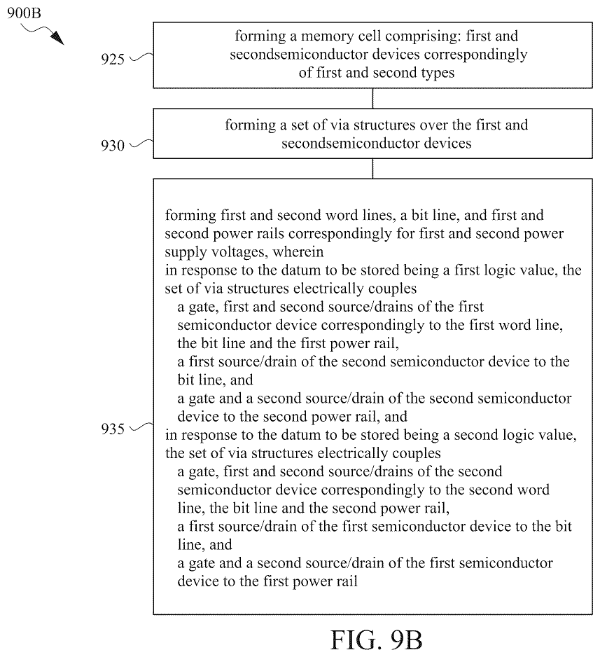

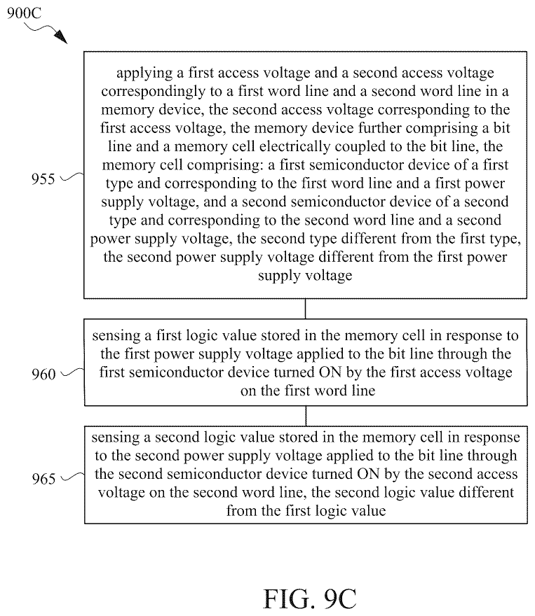

FIG. 9A is a flow chart of a method 900A of manufacturing a memory device, in accordance with some embodiments. In some embodiments, the method 900A is applicable to manufacture one or more memory devices, e.g., ROM devices, as described with respect to FIGS. 2A-2C, 4A-4E, 5A-5C, 6A-6C, 7A-7C, 8A-8C. The method 900A comprises operations 905, 910, 915.

At operation 905, a first semiconductor device and a second semiconductor device correspondingly of different first and second types are formed over a substrate. For example, an N-type transistor NM and a P-type transistor PM are formed in a stacked configuration or a planar configuration, as described with respect to FIGS. 4A, 4D.

At operation 910, a set of via structures is formed over the first and second semiconductor devices. For example, one or more VD, VG vias are formed over the transistor NM and transistor PM, as described with respect to FIGS. 4B, 4C. In some embodiments, one or more via structures in the set of via structures are formed, or omitted, depending on the datum to be stored in each memory cell. Operation 910 corresponds to a process referred to as ROM coding, in one or more embodiments.

At operation 915, first and second word lines, a bit line, and first and second power rails correspondingly for first and second power supply voltages are formed, for example, as described with respect to FIGS. 4B, 4C.

In response to the datum to be stored being a first logic value, e.g., logic “0”, the set of via structures electrically couples a gate, first and second source/drains of the first semiconductor device, e.g., the transistor N20, correspondingly to the first word line, the bit line and the first power rail (e.g., VSS), and electrically couples a first source/drain of the second semiconductor device, e.g., the transistor P20, to the bit line, and a gate of the second semiconductor device to the second word line, while leaving a second source/drain of the second semiconductor device floating, as described with respect to the memory cell MC20 in FIGS. 2A, 2B.

In response to the datum to be stored being a second logic value, e.g., logic “1”, the set of via structures electrically couples a gate, first and second source/drains of the second semiconductor device, e.g., the transistor P21, correspondingly to the second word line, the bit line and the second power rail (e.g., VDD), and electrically couples a first source/drain of the first semiconductor device, e.g., the transistor N21, to the bit line, and a gate of the first semiconductor device to the first word line, while leaving a second source/drain of the first semiconductor device floating, as described with respect to the memory cell MC21 in FIGS. 2A, 2B. In some embodiments, one or more advantages described herein are achievable by one or more memory devices manufactured by the method 900A.

FIG. 9B is a flow chart of a method 900B of manufacturing a memory device, in accordance with some embodiments. In some embodiments, the method 900B is applicable to manufacture one or more memory devices, e.g., ROM devices, as described with respect to FIGS. 3A-3C, 4A-4E, 5A-5C, 6A-6C, 7A-7C, 8A-8C. The method 900B comprises operations 925, 930, 935.

At operation 925, a first semiconductor device and a second semiconductor device correspondingly of different first and second types are formed over a substrate. For example, an N-type transistor NM and a P-type transistor PM are formed in a stacked configuration or a planar configuration, as described with respect to FIGS. 4A, 4D.

At operation 930, a set of via structures is formed over the first and second semiconductor devices. For example, one or more VD, VG vias are formed over the transistor NM and transistor PM, as described with respect to FIGS. 4B, 4C.

At operation 935, first and second word lines, a bit line, and first and second power rails correspondingly for first and second power supply voltages are formed, for example, as described with respect to FIGS. 4B, 4C.

In response to the datum to be stored being a first logic value, e.g., logic “0”, the set of via structures electrically couples a gate, first and second source/drains of the first semiconductor device, e.g., the transistor N30, correspondingly to the first word line, the bit line and the first power rail (e.g., VSS), and electrically couples a first source/drain of the second semiconductor device, e.g., the transistor P30, to the bit line, and a gate and a second source/drain of the second semiconductor device to the second power rail (e.g., VDD), as described with respect to the memory cell MC30 in FIGS. 3A, 3B.

In response to the datum to be stored being a second logic value, e.g., logic “1”, the set of via structures electrically couples a gate, first and second source/drains of the second semiconductor device, e.g., the transistor P31, correspondingly to the second word line, the bit line and the second power rail (e.g., VDD), and electrically couples a first source/drain of the first semiconductor device, e.g., the transistor N31, to the bit line, and a gate and a second source/drain of the first semiconductor device to the first power rail (e.g., VSS), as described with respect to the memory cell MC31 in FIGS. 3A, 3B. The connection of a second source/drain of a P-type transistor or an N-type transistor to VDD or VSS corresponds to ROM coding, in one or more embodiments. In some embodiments, one or more advantages described herein are achievable by one or more memory devices manufactured by the method 900B.

FIG. 9C is a flow chart of a method 900C of operating a memory device, in accordance with some embodiments. In some embodiments, the method 900C is performed in a read operation of a selected memory cell as described with respect to FIGS. 1, 2A-2C, 3A-3C. The method 900C comprises operations 955, 960, 965.

At operation 955, a first access voltage and a second access voltage are applied correspondingly to a first word line and a second word line in a memory device, the second access voltage corresponding to the first access voltage. For example, as described with respect to FIGS. 2A-2B, 3A-3B, access voltages VsWLn, VsWLp, which are inverted signals, are applied to the corresponding word lines of a selected memory cell. The memory device further comprises a bit line (e.g., BL) and a memory cell electrically coupled to the bit line and comprising: a first semiconductor device (e.g., an N-type transistor) of a first type and corresponding to the first word line and a first power supply voltage (e.g., VSS), and a second semiconductor device (e.g., a P-type transistor) of a second type and corresponding to the second word line and a second power supply voltage (e.g., VDD).

At operation 960, a first logic value stored in the memory cell is sensed in response to the first power supply voltage applied to the bit line through the first semiconductor device turned ON by the first access voltage on the first word line. For example, as described with respect to FIGS. 2A, 3A, a first logic value, e.g., logic “0”, stored in the selected memory cell is sensed, e.g., by a sense amplifier SA, in response to the first power supply voltage, e.g., VSS, applied to the bit line BL through the first semiconductor device, e.g., the transistor N20 or N30, turned ON by the first access voltage, e.g., VsWLn, on the first word line, e.g., WLn0.

At operation 965, a second logic value stored in the memory cell is sensed in response to the second power supply voltage applied to the bit line through the second semiconductor device turned ON by the second access voltage on the second word line. For example, as described with respect to FIGS. 2B, 3B, a second logic value, e.g., logic “1”, stored in the selected memory cell is sensed, e.g., by the sense amplifier SA, in response to the second power supply voltage, e.g., VDD, applied to the bit line BL through the second semiconductor device, e.g., the transistor P21 or P31, turned ON by the second access voltage, e.g., VsWLp, on the second word line, e.g., WLp1. In at least one embodiment, one or more advantages described herein are achievable by the method 900C.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

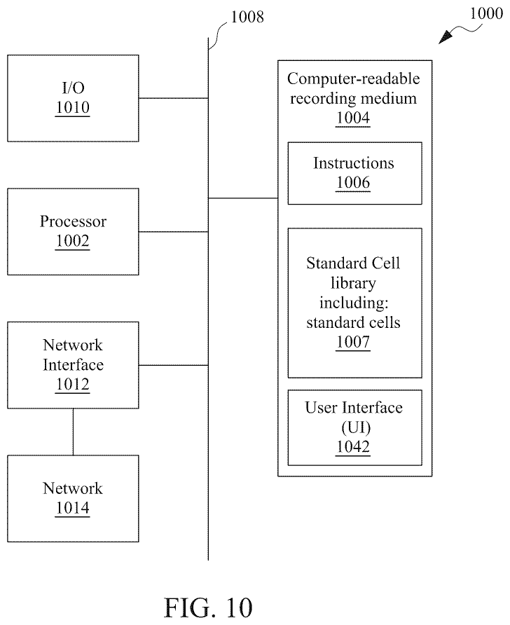

FIG. 10 is a block diagram of an electronic design automation (EDA) system 1000 in accordance with some embodiments.

In some embodiments, EDA system 1000 includes an APR system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable recording medium 1004. Recording medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable recording medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable recording medium 1004 are capable of connecting to external elements via network 1014. Processor 1002 is configured to execute computer program code 1006 encoded in computer-readable recording medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable recording medium 1004 is an electronic, magnetic, optical, electromagnetic, infrared, and/or a semiconductor system (or apparatus or device). For example, computer-readable recording medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 1004 includes a compact disk-read only memory (CD-ROM), a compact disk-read/write (CD-R/W), and/or a digital video disc (DVD).

In one or more embodiments, recording medium 1004 stores computer program code 1006 configured to cause system 1000 (where such execution represents (at least in part) the EDA tool) to be usable for performing a portion or all of the noted processes and/or methods. In one or more embodiments, recording medium 1004 also stores information which facilitates performing a portion or all of the noted processes and/or methods. In one or more embodiments, recording medium 1004 stores library 1007 of standard cells including such standard cells as disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable recording medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

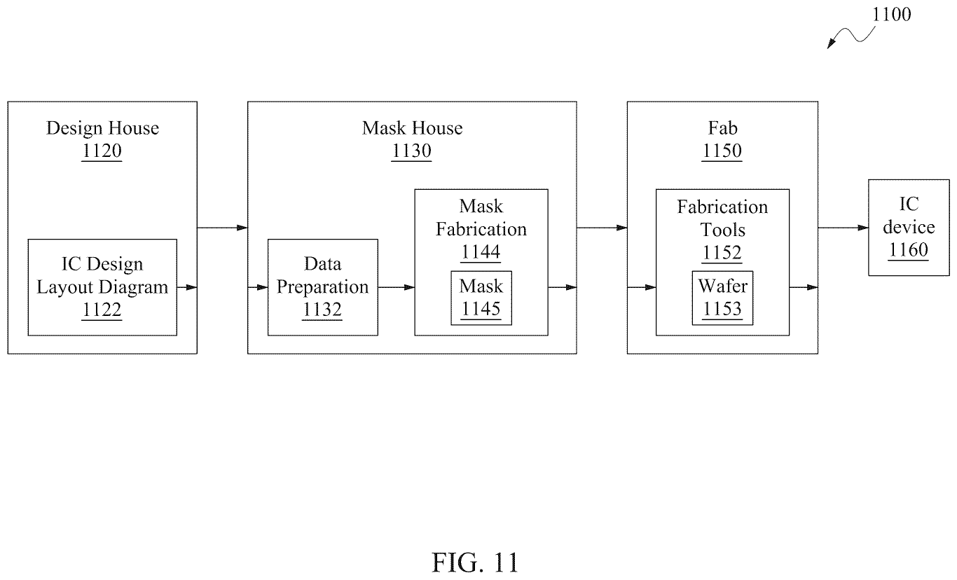

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place-and-route operation. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, a memory device comprises a first word line, a second word line, a bit line, and a memory cell. The memory cell comprises a first semiconductor device of a first type, and a second semiconductor device of a second type different from the first type. The first semiconductor device comprises a gate electrically coupled to the first word line, a first source/drain electrically coupled to the bit line, and a second source/drain electrically coupled to receive a first power supply voltage. The second semiconductor device comprises a gate, a first source/drain electrically coupled to the bit line, and a second source/drain. The second word line is electrically coupled to the gate of the second semiconductor device, and the second source/drain of the second semiconductor device is floating. Alternatively, the gate of the second semiconductor device and the second source/drain of the second semiconductor device are electrically coupled to receive a second power supply voltage different from the first power supply voltage.

In some embodiments, a memory device comprises a first active region of a first type, a second active region of a second type different from the first type, at least one first gate and at least one second gate extending across the first active region, and at least one third gate and at least one fourth gate extending across the second active region. The at least one first gate and the at least one second gate correspondingly configure, together with the first active region, a first transistor and a second transistor. The at least one third gate and the at least one fourth gate correspondingly configure, together with the second active region, a third transistor and a fourth transistor. A first bit line pattern is over the first active region, and electrically coupled to a first source/drain of the first transistor and a first source/drain of the second transistor. A second bit line pattern is over the second active region, and electrically coupled to the first bit line pattern, a first source/drain of the third transistor and a first source/drain of the fourth transistor. A first power rail configured to carry a first power supply voltage is over the first active region, electrically coupled to a second source/drain of the first transistor, and electrically isolated from a second source/drain of the second transistor. A second power rail configured to carry a second power supply voltage different from the first power supply voltage is over the second active region, electrically coupled to a second source/drain of the fourth transistor, and electrically isolated from a second source/drain of the third transistor.

A method in accordance with some embodiments comprises applying a first access voltage and a second access voltage correspondingly to a first word line and a second word line in a memory device. The second access voltage corresponds to the first access voltage. The memory device further comprises a bit line and a memory cell electrically coupled to the bit line. The memory cell comprises a first semiconductor device of a first type and corresponding to the first word line and a first power supply voltage, and a second semiconductor device of a second type and corresponding to the second word line and a second power supply voltage. The second type is different from the first type, and the second power supply voltage is different from the first power supply voltage. The method further comprises sensing a first logic value stored in the memory cell in response to the first power supply voltage applied to the bit line through the first semiconductor device turned ON by the first access voltage on the first word line, and sensing a second logic value stored in the memory cell in response to the second power supply voltage applied to the bit line through the second semiconductor device turned ON by the second access voltage on the second word line, the second logic value different from the first logic value.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a first word line;
a second word line;
a bit line; and
a memory cell which comprises:
a first semiconductor device of a first type, the first semiconductor device comprising:
a gate electrically coupled to the first word line,
a first source/drain electrically coupled to the bit line, and
a second source/drain electrically coupled to receive a first power supply voltage; and
a second semiconductor device of a second type different from the first type, the second semiconductor device comprising:
a gate,
a first source/drain electrically coupled to the bit line, and
a second source/drain; wherein
the second word line is electrically coupled to the gate of the second semiconductor device, and the second source/drain of the second semiconductor device is floating, or
the gate of the second semiconductor device and the second source/drain of the second semiconductor device are electrically coupled to receive a second power supply voltage different from the first power supply voltage.

2. The memory device of claim 1, wherein the first semiconductor device and the second semiconductor device are configured to together store a logic value.

3. The memory device of claim 1, wherein
the second word line is electrically coupled to the gate of the second semiconductor device, and
the second source/drain of the second semiconductor device is floating.

4. The memory device of claim 3, further comprising:
a further bit line; and
a further memory cell which comprises:
a third semiconductor device of the first type, the third semiconductor device comprising:
a gate electrically coupled to the first word line,
a first source/drain electrically coupled to the further bit line, and
a second source/drain which is floating; and
a fourth semiconductor device of the second type, the fourth semiconductor device comprising:
a gate electrically coupled to the second word line,
a first source/drain electrically coupled to the further bit line, and
a second source/drain electrically coupled to receive the second power supply voltage.

5. The memory device of claim 4, wherein
the first semiconductor device and the second semiconductor device are configured to together store a first logic value, and
the third semiconductor device and the fourth semiconductor device are configured to together store a second logic value different from the first logic value.

6. The memory device of claim 1, wherein
the gate of the second semiconductor device and the second source/drain of the second semiconductor device are electrically coupled to receive the second power supply voltage different from the first power supply voltage.

7. The memory device of claim 6, further comprising:
a further bit line; and
a further memory cell which comprises:
a third semiconductor device of the first type, the third semiconductor device comprising:
a gate,
a first source/drain electrically coupled to the further bit line, and
a second source/drain, wherein the gate of the third semiconductor device and the second source/drain of the third semiconductor device are electrically coupled to receive the first power supply voltage; and
a fourth semiconductor device of the second type, the fourth semiconductor device comprising:
a gate electrically coupled to the second word line,
a first source/drain electrically coupled to the further bit line, and
a second source/drain electrically coupled to receive the second power supply voltage.

8. The memory device of claim 7, wherein
the first semiconductor device and the second semiconductor device are configured to together store a first logic value, and
the third semiconductor device and the fourth semiconductor device are configured to together store a second logic value different from the first logic value.

9. The memory device of claim 1, wherein
the first semiconductor device and the second semiconductor device configure a complementary field effect transistor (CFET) device in which the first semiconductor device is over or under the second semiconductor device.

10. The memory device of claim 9, wherein
the gate of the first semiconductor device and the gate of the second semiconductor device have different numbers of gate fingers.

11. A memory device, comprising:
a first active region of a first type;
a second active region of a second type different from the first type;
at least one first gate and at least one second gate extending across the first active region, and correspondingly configuring, together with the first active region, a first transistor and a second transistor;
at least one third gate and at least one fourth gate extending across the second active region, and correspondingly configuring, together with the second active region, a third transistor and a fourth transistor;
a first bit line pattern over the first active region, and electrically coupled to a first source/drain of the first transistor and a first source/drain of the second transistor;
a second bit line pattern over the second active region, and electrically coupled to the first bit line pattern, a first source/drain of the third transistor and a first source/drain of the fourth transistor;
a first power rail configured to carry a first power supply voltage, over the first active region, electrically coupled to a second source/drain of the first transistor, and electrically isolated from a second source/drain of the second transistor; and
a second power rail configured to carry a second power supply voltage different from the first power supply voltage, over the second active region, electrically coupled to a second source/drain of the fourth transistor, and electrically isolated from a second source/drain of the third transistor.

12. The memory device of claim 11, wherein
the first transistor and the third transistor are configured to together store a first logic value, and
the second transistor and the fourth transistor are configured to together store a second logic value different from the first logic value.

13. The memory device of claim 11, further comprising:
a controller configured to, in a read operation,
supply a first pair of inverted signals correspondingly to the at least one first gate and the at least one second gate, and
supply a second pair of inverted signals correspondingly to the at least one third gate and the at least one fourth gate, the second pair of inverted signals different from the first pair of inverted signals.

14. The memory device of claim 11, wherein at least one of
the at least one first gate and the at least one third gate have different numbers of gate fingers, or
the at least one second gate and the at least one fourth gate have different numbers of gate fingers.

15. The memory device of claim 11, further comprising, at least one of:
between the first transistor and the second transistor,
a dummy gate electrically coupled to receive the first power supply voltage, or
an isolation structure physically disconnecting the first and second source/drains of the first transistor from the first and second source/drains of the second transistor, or
between the third transistor and the fourth transistor,
a further dummy gate electrically coupled to receive the second power supply voltage, or
a further isolation structure physically disconnecting the first and second source/drains of the third transistor from the first and second source/drains of the fourth transistor.

16. The memory device of claim 11, wherein
the first active region, the at least one first gate and the at least one second gate correspondingly overlap the second active region, the at least one third gate, the at least one fourth gate along a thickness direction of the memory device.

17. A method, comprising:
applying a first access voltage and a second access voltage correspondingly to a first word line and a second word line in a memory device, the second access voltage corresponding to the first access voltage, the memory device further comprising a bit line and a memory cell electrically coupled to the bit line, the memory cell comprising:
a first semiconductor device of a first type and corresponding to the first word line and a first power supply voltage, and
a second semiconductor device of a second type and corresponding to the second word line and a second power supply voltage, the second type different from the first type, the second power supply voltage different from the first power supply voltage;
sensing a first logic value stored in the memory cell in response to the first power supply voltage applied to the bit line through the first semiconductor device turned ON by the first access voltage on the first word line; and
sensing a second logic value stored in the memory cell in response to the second power supply voltage applied to the bit line through the second semiconductor device turned ON by the second access voltage on the second word line, the second logic value different from the first logic value.

18. The method of claim 17, wherein
the second access voltage is an inverted signal of the first access voltage.

19. The method of claim 17, wherein
the first logic value stored in the memory cell corresponds to the second semiconductor device disconnected from either the second word line or the second power supply voltage, or
the second logic value stored in the memory cell corresponds to the first semiconductor device disconnected from either the first word line or the first power supply voltage.

20. The method of claim 17, wherein
the first power supply voltage is the ground, and
said sensing the first logic value stored in the memory cell is performed without a further circuit causing a current to flow through the bit line and the turned ON first semiconductor device to the ground during said sensing the first logic value.
